(19) United States
(12) Patent Application Publication
(10) Pub. No.: US 2024/0081064 A1
(43) Pub. Date: Mar. 7, 2024

(54) SEMICONDUCTOR DEVICES AND DATA STORAGE SYSTEMS INCLUDING THE SAME

(71) Applicant: Samsung Electronics Co., Ltd., Suwon-si (KR)

(72) Inventors: Euntaek Jung, Suwon-si (KR); Sukkang Sung, Suwon-si (KR)

(21) Appl. No.: 18/452,919

(22) Filed: Aug. 21, 2023

(30) Foreign Application Priority Data
Sep. 2, 2022 (KR) 10-2022-0111633

(51) Int. Cl. H10B 43/27; H10B 41/27; H10B 41/35; H10B 43/35

(52) U.S. Cl. CPC H10B 43/27; H10B 41/27; H10B 41/35; H10B 43/35

(57) ABSTRACT

According to some embodiments of the present disclosure, a semiconductor device is provided. A gate electrode structure includes a plurality of first gate electrode layers separated by interlayer insulating layers on a substrate. A plurality of first channel structures extend through the gate electrode structure. An insulating layer is on the first channel structures and the gate electrode structure. A second gate electrode layer is on the insulating layer. A plurality of second channel structures extends through the second gate electrode layer. Each of the second channel structures is electrically coupled with one of the first channel structures, and each of the second channel structures includes a first portion extending through the second gate electrode layer and a second portion on the first portion. The first portion has a first width, and the second portion has a second width that is greater than the first width.

### CROSS-REFERENCE TO RELATED APPLICATION(S)

This application claims the benefit of priority under 35 U.S.C. § 119 of Korean Patent Application No. 10-2022-0111633 filed on Sep. 2, 2022, in the Korean Intellectual Property Office, the disclosure of which is hereby incorporated herein by reference in its entirety.

### BACKGROUND

The present disclosure relates to semiconductor devices and data storage systems including the same.

In a data storage system using/requiring data storage, a semiconductor device capable of storing high-capacity data may be useful/required. Accordingly, methods to increase data storage capacity of semiconductor devices are being studied. For example, to increase data storage capacity of semiconductor devices, semiconductor devices including three-dimensionally arranged memory cells, instead of two-dimensionally arranged memory cells, have been proposed.

### SUMMARY

Some example embodiments may provide semiconductor devices and/or data storage systems with improved integration and/or reliability.

According to some example embodiments, a semiconductor device includes a substrate, first gate electrodes, first channel structures, separation regions, an insulating layer, a plurality of conductive patterns, a second gate electrode, second channel structures, and isolation regions. The first gate electrodes are spaced apart from each other and stacked on the substrate. The first channel structures extend through the first gate electrodes in a first direction that is perpendicular with respect to a surface of the substrate, wherein each of the first channel structures respectively includes a first channel layer and a first dielectric layer between the first channel layer and each of the first gate electrodes. The separation regions extend through the first gate electrodes in the first direction and extend in a second direction that is parallel with respect to the surface of the substrate, wherein adjacent ones of the separation regions are spaced apart from each other in a third direction that is perpendicular with respect to the first and second directions and that is parallel with respect to the surface of the substrate. The insulating layer is on the first channel structures and the separation regions, wherein the separation regions are between the insulating layer and the substrate. The plurality of conductive patterns pass through the insulating layer, wherein each of the conductive patterns is connected to a respective one of the first channel structures. The second gate electrode is on the insulating layer. The second channel structures extend through the second gate electrode, wherein each of the second channel structures respectively includes a second channel layer connected to a respective one of the conductive patterns and a second dielectric layer between the second channel layer and the second gate electrode. The isolation regions extend through the second gate electrode, wherein the insulating layer is between the isolation regions and the substrate. Each of the first channel structures includes a respective first region overlapping a respective one of the second channel structures in the first direction, and a respective second region that is non-overlapping with the respective one of the second channel structures in the first direction. Each of the second channel structures includes a first portion having a first width in the third direction and a second portion having a second width in the third direction that is greater than the first width, wherein the first portion is between the second portion and the substrate.

According to some example embodiments, a semiconductor device includes a substrate, gate electrode layers on the substrate, channel structures, an insulating layer, a plurality of conductive patterns, a conductive layer, and a plurality of semiconductor structures. The gate electrode layers are spaced apart from each other and stacked on the substrate. The channel structures extend through the gate electrode layers in a first direction that is perpendicular with respect to a surface of the substrate, wherein each of the channel structures respectively includes a channel layer and a dielectric layer between the channel layer and the gate electrode layers. The insulating layer is on the channel structures and the gate electrode layers. The plurality of conductive patterns pass through the insulating layer, wherein each of the conductive patterns is connected to a respective one of the channel structures. The conductive layer is on the insulating layer and on the conductive patterns. Each of the semiconductor structures extends through the conductive layer and is connected to a respective one of the conductive patterns. Each of the semiconductor structures includes a first portion extending through the conductive layer, a second portion on the first portion, and a third portion between the first portion and the substrate. The second portion is on a portion of the conductive layer opposite the substrate. The third portion is on a portion of the conductive layer between the conductive layer and the substrate.

According to some example embodiments, a data storage system includes a semiconductor storage device, and a controller. The semiconductor storage device includes a first substrate, circuit elements on one side of the first substrate, a second substrate on the circuit elements, gate electrodes, channel structures, an insulating layer on the channel structures, a plurality of conductive patterns, a conductive layer, a plurality of semiconductor structures, and an input/output pad. The gate electrodes are spaced apart from each other and stacked in a first direction that is perpendicular with respect to a surface of the second substrate, wherein the gate electrodes are stacked between the first and second substrates. The channel structures extend through the gate electrodes in the first direction, wherein each of the channel structures respectively includes a channel layer and a dielectric layer between the channel layer and the gate electrodes. The plurality of conductive patterns pass through the insulating layer, wherein each of the conductive patterns is connected to a respective one of the channel structures. The conductive layer is on the insulating layer and the conductive patterns. The plurality of semiconductor structures extend through the conductive layer, wherein each of the semiconductor structures is connected to a respective one of the conductive patterns. The input/output pad is electrically connected to at least one of the circuit elements. The controller is electrically connected to the semiconductor storage device through the input/output pad, wherein the controller is configured to control the semiconductor storage device. Each of the semiconductor structures includes a first portion extending through the conductive layer, a second portion on the first portion, and a third portion between the first portion and the gate electrodes. The second portion is on a portion of a first surface of the conductive layer opposite the gate electrodes, and the third portion is on a portion of a second surface of the conductive layer adjacent the gate electrodes.

According to some example embodiments, a semiconductor device includes a substrate, a gate electrode structure on the substrate, a plurality of first channel structures, an insulating layer, a second gate electrode, and a plurality of second channel structures. The gate electrode structure includes a plurality of first gate electrode layers separated by interlayer insulating layers. The plurality of first channel structures extend through the first gate electrode layers and interlayer insulating layers of the gate electrode structure in a first direction that is perpendicular with respect to a surface of the substrate. The insulating layer is on the plurality of first channel structures and is on the gate electrode structure so that the gate electrode structure is between the insulating layer and the substrate. The second gate electrode layer is on the insulating layer so that the insulating layer is between the second gate electrode layer and the gate electrode structure. The plurality of second channel structures extends through the second gate electrode layer. Each of the second channel structures is electrically coupled with a respective one of the first channel structures, and each of the second channel structures includes a first portion extending through the second gate electrode layer and a second portion on the first portion so that first portion is between the second portion and the substrate. The first portion has a first width in a second direction that is parallel with respect to the surface of the substrate, and the second portion has a second width in the second direction that is greater than the first width.

### BRIEF DESCRIPTION OF DRAWINGS

The above and other aspects, features, and advantages of some example embodiments of present inventive concepts will be more apparent from the following description taken in conjunction with the accompanying drawings, in which:

FIGS. 1A and 1B are plan views of a semiconductor device according to some example embodiments where FIG. 1B is an enlarged view of area A of FIG. 1A;

FIG. 2 is a cross-sectional view of a semiconductor device according to some example embodiments;

FIG. 3 is an enlarged view of area B of the semiconductor device of FIG. 2;

FIGS. 4A, 4B, 4C, 4D and 4E are enlarged views illustrating alternatives of area B of a semiconductor device according to some example embodiments;

FIG. 5 is an enlarged view of area B a semiconductor device according to some example embodiments;

FIG. 6 is a cross-sectional view of a semiconductor device according to some example embodiments;

FIG. 7 is a cross-sectional view of a semiconductor device according to some example embodiments;

FIGS. 8A and 8B are cross-sectional views of a semiconductor device according to some example embodiments;

FIGS. 9A, 9B, 9C, 9D, 9E, 9F, 9G, 9H, 9I, 9J and 9K are cross-sectional views and enlarged views illustrating operations of manufacturing a semiconductor device according to some example embodiments;

FIG. 10 is a schematic diagram illustrating a data storage system including a semiconductor device according to some example embodiments;

FIGS. 11A and 11B are perspective views illustrating a data storage system including a semiconductor device according to some example embodiments; and

FIGS. 12A and 12B are schematic cross-sectional views of a semiconductor package according to some example embodiments.

### DETAILED DESCRIPTION

Hereinafter, various embodiments will be described in detail with reference to the accompanying drawings.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof. The term “and/or” includes any and all combinations of one or more of the associated listed items.

Spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present inventive concepts.

It will also be understood that when an element is referred to as being “on” or “connected to” or “in contact with” another element, it can be directly on or connected to or in contact with the other element, or intervening elements may be present. In contrast, when an element is referred to as being “directly on” or “directly connected to” or “in direct contact with” another element, there are no intervening elements present.

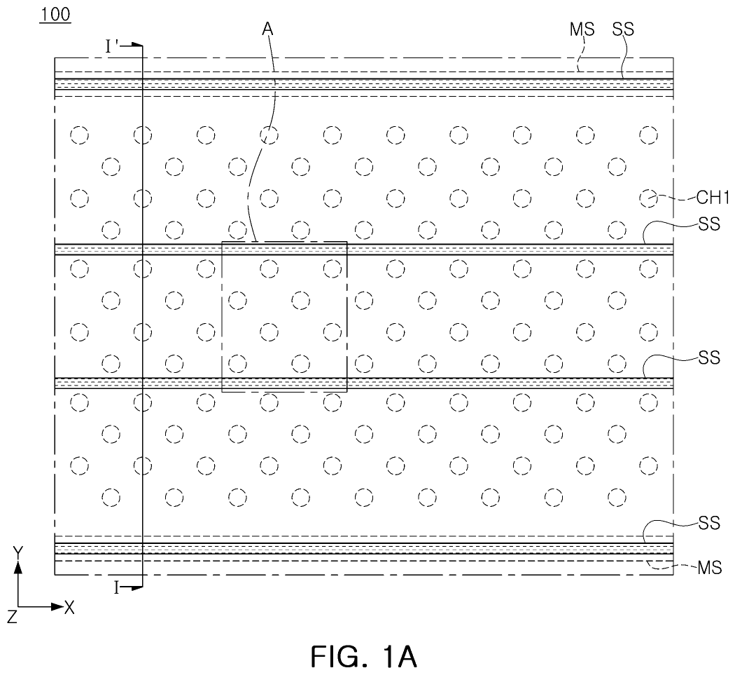

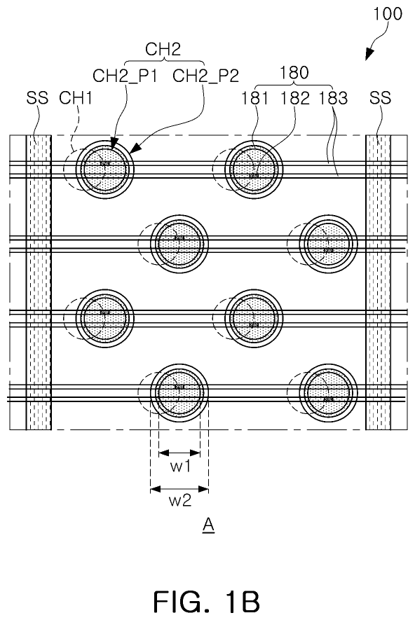

FIGS. 1A and 1B are plan views of a semiconductor device according to some example embodiments. FIG. 1B is an enlarged view of area ‘A’ of FIG. 1A.

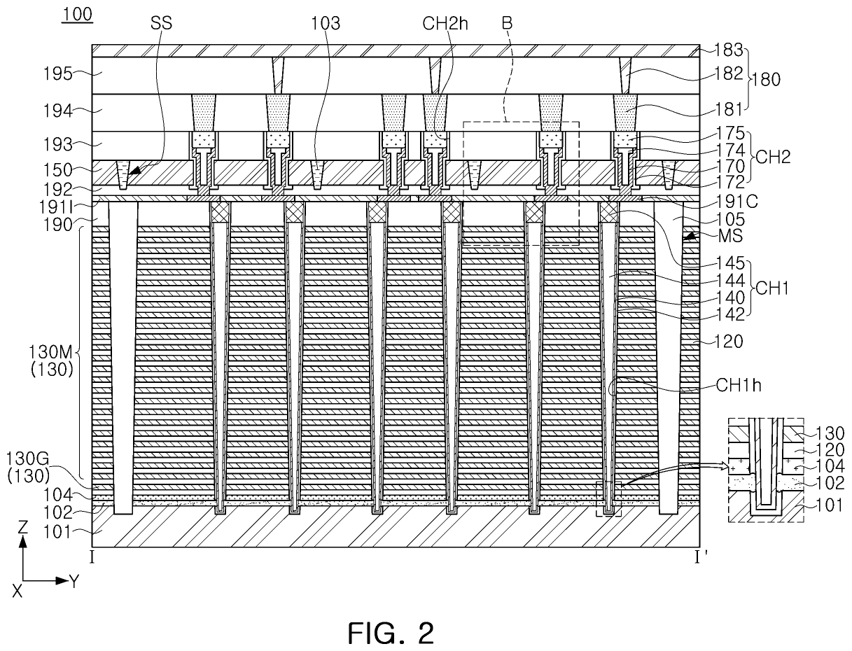

FIG. 2 is a cross-sectional view of a semiconductor device according to some example embodiments. FIG. 2 illustrates a cross section taken along line I-I′ in FIG. 1A.

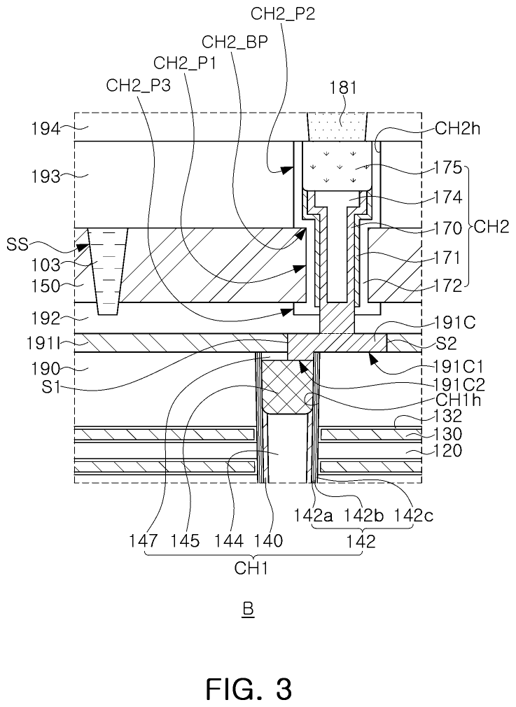

FIG. 3 is a partially enlarged view of a semiconductor device according to some example embodiments. FIG. 3 is an enlarged view of area ‘B’ of FIG. 2.

Referring to FIGS. 1A to 3, a semiconductor device 100 may include a substrate 101, first and second horizontal conductive layers 102 and 104 on the substrate 101, first gate electrodes 130 stacked on the substrate 101, interlayer insulating layers 120 alternately stacked with the first gate electrodes 130 on the substrate 101, first channel structures CH1 disposed to penetrate through the stack structure formed of the first gate electrodes 130 and the interlayer insulating layers 120 and respectively including the first channel layer 140, separation regions MS penetrating through the stack structure, an insulating pattern 191I on the first channel structures CH1 and the separation regions MS, a second gate electrode 150 on the insulating pattern 191I, second channel structures CH2 disposed to pass through the second gate electrode 150 and respectively including a second channel layer 170, and upper isolation regions SS extending by penetrating through the second gate electrode 150. The semiconductor device 100 may further include a cell region insulating layer 190 covering the stack structure, below the insulating pattern 191I, upper insulating layers 192, 193, 194 and 195 on the cell region insulating layer 190, and an upper interconnection structure 180 connected to the respective second channel structures CH2.

As illustrated in FIG. 1A, in the semiconductor device 100, one memory cell string may be formed around each first channel structure CH1, and a plurality of memory cell strings may be arranged in columns and rows in the X and Y-directions.

The substrate 101 may have an upper surface extending in the X and Y-directions. The substrate 101 may include a semiconductor material, such as a Group IV semiconductor, a Group III-V compound semiconductor, or a Group II-VI compound semiconductor. For example, the group IV semiconductor may include silicon, germanium, or silicon-germanium. The substrate 101 may be provided as a bulk wafer, an epitaxial layer, a Silicon On Insulator (SOI) layer, or a Semiconductor On Insulator (SeOI) layer.

The first and second horizontal conductive layers 102 and 104 may be stacked and disposed on the upper surface of the substrate 101. The first horizontal conductive layer 102 may function as at least a portion of a common source line of the semiconductor device 100, and may function as a common source line together with the substrate 101. As illustrated in the enlarged view of FIG. 2, the first horizontal conductive layer 102 may be directly connected to the first channel layer 140 around the first channel layer 140.

The first and second horizontal conductive layers 102 and 104 may each include a semiconductor material, for example polycrystalline silicon. In this case, at least the first horizontal conductive layer 102 may be a layer doped with impurities of the same conductivity type as the substrate 101, and the second horizontal conductive layer 104 may be a doped layer or may be a layer including impurities diffused from the first horizontal conductive layer 102. However, the material of the second horizontal conductive layer 104 is not limited to a semiconductor material, and may be replaced with a metal layer according to some example embodiments.

The first gate electrodes 130 may be vertically spaced apart and stacked on the substrate 101 to form a stack structure. The first gate electrodes 130 may include a lower gate electrode 130G forming a gate of a ground select transistor, and memory gate electrodes 130M forming gates for a plurality of memory cells. The number of memory gate electrodes 130M for respective memory cells may be determined according to the capacity of the semiconductor device 100. According to some example embodiments, one or more lower gate electrodes 130G may be formed, and may have the same structure as or a different structure from the memory gate electrodes 130M. In some example embodiments, the first gate electrodes 130 may further include a gate electrode 130 disposed below the lower gate electrode 130G and as a gate for an erase transistor used for an erase operation using a gate induced drain leakage (GIDL) phenomenon. Also, some of the first gate electrodes 130, for example, memory gate electrodes 130M adjacent to the lower gate electrode 130G, may be dummy gate electrodes.

The first gate electrodes 130 may include a metal material, such as tungsten (W). Depending on the embodiment, the first gate electrodes 130 may include polycrystalline silicon or a metal silicide material. In some example embodiments, the first gate electrodes 130 may further include a diffusion barrier. For example, the diffusion barrier may include tungsten nitride (WN), tantalum nitride (TaN), or titanium nitride (TiN), or combinations thereof.

The interlayer insulating layers 120 may be disposed between the first gate electrodes 130. Like the first gate electrodes 130, the interlayer insulating layers 120 may also be disposed to be spaced apart from each other in a direction perpendicular to the upper surface of the substrate 101. The interlayer insulating layers 120 may include an insulating material such as silicon oxide or silicon nitride.

Each of the first channel structures CH1 may respectively form one memory cell string, and the first channel structures CH1 may be spaced apart from each other while forming rows and columns on the substrate 101. The first channel structures CH1 may be disposed to form a lattice pattern in an X-Y plane or may be disposed in a zigzag shape in one direction. In some example embodiments, the first channel structures CH1 may be disposed in a zigzag pattern with six channel structures arranged in a first column and six channel structures arranged in a second column between adjacent separation regions MS as shown in FIG. 1A, but the arrangement of the first channel structures CH1 is not limited thereto and may be variously changed. Each of the first channel structures CH1 may have a columnar shape and may have inclined side surfaces (also referred to as sidewalls) that become narrower closer to the substrate 101 according to an aspect ratio. As illustrated in the enlarged view of FIG. 2, each of the first channel structures CH1 may further include a first dielectric layer 142, a first filling insulating layer 144 between the first channel layers 140, and a first channel pad 145 on an upper end of the first filling insulating layer 144, in addition to the first channel layer 140.

The first channel layer 140 may be formed in an annular shape surrounding the first filling insulating layer 144 therein, but may have a pillar shape such as a cylinder or a prism without the first filling insulating layer 144 according to some example embodiments. The first channel layer 140 may be connected to the first horizontal conductive layer 102 on the lower portion thereof. The first channel layer 140 may include a semiconductor material such as polycrystalline silicon or single crystal silicon, and the semiconductor material may be an undoped material or a material containing p-type or n-type impurities.

The first dielectric layer 142 may be disposed between respective first gate electrodes 130 and the first channel layer 140. Referring to FIG. 3, the first dielectric layer 142 may include a tunneling layer 142a, a charge storage layer 142b, and a blocking layer 142c sequentially stacked from the first channel layer 140. The tunneling layer 142a may tunnel charges into the charge storage layer 142b, and may include, for example, silicon oxide (SiO₂), silicon nitride (Si₃N₄), silicon oxynitride (SiON), or combinations thereof. The charge storage layer 142b may be a charge trap layer or a floating gate conductive layer. The blocking layer 142c may include silicon oxide (SiO₂), silicon nitride (Si₃N₄), silicon oxynitride (SiON), a high-k dielectric material, or combinations thereof. In some example embodiments, the semiconductor device 100 may further include a gate dielectric layer 132 disposed between the first gate electrodes 130 and the interlayer insulating layers 120 and between the first gate electrodes 130 and the first channel structures CH1. The gate dielectric layer 132 may serve to reduce/prevent charges in the charge storage layer 142b from moving to the first gate electrodes 130, together with the blocking layer 142c.

Each first channel pad 145 may cover the upper surface of the respective first filling insulating layer 144 and may be electrically connected to the respective first channel layer 140. Each first channel pad 145 may be disposed on the respective first channel layer 140. The first channel pad 145 may include, for example, polycrystalline silicon.

The separation regions MS extend in the Z-direction by penetrating through the first gate electrodes 130, the interlayer insulating layers 120, and the first and second horizontal conductive layers 102 and 104, and the separation regions MS extend in the X-direction, and may be connected to the substrate 101. As illustrated in FIG. 1A, the separation regions MS may be spaced apart from each other and disposed in parallel in the Y-direction. The separation regions MS may have a trench shape extending in the X-direction. The separation regions MS may divide the first gate electrodes 130 from each other in the Y-direction. The separation regions MS may have a shape in which a width decreases toward the substrate 101 due to a high aspect ratio. An isolation insulating layer 105 may be disposed in the separation regions MS. The isolation insulating layer 105 may include at least one of silicon oxide, silicon nitride, and silicon oxynitride. However, according to another embodiments, a conductive material layer may be disposed in the separation regions MS.

The cell region insulating layer 190 may cover the stack structure formed of the first gate electrodes 130 and the interlayer insulating layers 120. The cell region insulating layer 190 may cover at least a portion of the side surfaces of the separation regions MS and/or the first channel structures CH1, for example, a portion extending upward from the stack structure.

In some example embodiments, the upper surface of the cell region insulating layer 190 may be positioned at substantially the same level as the respective upper surfaces of the first channel structures CH1. An upper surface of the cell region insulating layer 190 may be positioned at substantially the same level as respective upper surfaces of the separation regions MS.

The cell region insulating layer 190 may include at least one of silicon oxide, silicon nitride, and silicon oxynitride.

The insulating pattern 191I may be disposed on the first channel structures CH1 and the separation regions MS. The insulating pattern 191I may be located at a higher level than a level of the stack structure and a level of the cell region insulating layer 190. The insulating pattern 191I may have a conformal thickness and may be disposed to extend in the X and Y-directions. The thickness of the insulating pattern 191I may be substantially equal to or smaller than the thickness of the first gate electrode 130. The insulating pattern 191I may include a material different from a material of the cell region insulating layer 190 to provide etch selectivity. The insulating pattern 191I may include the cell region insulating layer 190 and a material having etch selectivity. For example, the insulating pattern 191I may include at least one of nitride-based materials such as silicon nitride and silicon oxynitride.

In some example embodiments, the semiconductor device 100 may further include a conductive pattern 191C. The conductive pattern 191C may pass through the insulating pattern 191I and be connected to the first channel structures CH1. The conductive pattern 191C may be a structure filled in a plurality of holes having a shape such as a circle, an ellipse, or a polygon. In the vertical Z-direction, the conductive pattern 191C may partially overlap the first channel structures CH1. The conductive patterns 191C may include respective first side surfaces s1 contacting the insulating pattern 191I on first channel structures CH1 and respective second side surfaces s2 contacting the insulating pattern 191I on the first gate electrodes 130. In an some example embodiments, the length of the first side surface s1 in the Z-direction may be longer than the length of the second side surface s2 in the Z-direction, but some embodiments are not limited to this structure. Compared to the configuration of the height level where the insulating pattern 191I is disposed, a portion of each of the first channel structures CH1 may overlap the respective conductive pattern 191C, and the remaining portion may overlap the insulating pattern 191I. For example, on a plane, the center of each conductive pattern 191C may be spaced apart from the center of each of the respective first channel structures CH1.

The conductive pattern 191C may include a semiconductor material such as silicon (Si), germanium (Ge), or a mixture thereof.

In some example embodiments, each of the first channel structures CH1 may further include a capping pad 147. The capping pad 147 may be disposed between the insulating pattern 191I and the first channel pad 145. The upper surface of the capping pad 147 may be positioned at substantially the same level as the upper surface of the cell region insulating layer 190 and may be positioned at substantially the same level as the lower surface of the insulating pattern 191I. The capping pad 147 may have a thickness that is less than a thickness of the insulating pattern 191I. The capping pad 147 may include a material different from a material of the insulating pattern 191I. The capping pad 147 may include a material having etch selectivity with respect to the insulating pattern 191I. For example, the capping pad 147 may include an oxide-based material such as silicon oxide. The capping pad 147 may be configured to reduce/prevent defects due to etching of the first channel pad 145 occurring during an operation of forming the conductive pattern 191C. The conductive pattern 191C may pass through the capping pad 147 in an area overlapping the first channel structures CH1 and contact the first channel pad 145. The conductive pattern 191C may include a first conductive portion 191C1 on the cell region insulating layer 190 and a second conductive portion 191C2 on the first channel pad 145. A lower surface of the first conductive portion 191C1 may contact the cell region insulating layer 190 and a lower surface of the second conductive portion 191C2 may contact the first channel pad 145. Accordingly, the lower end of the second conductive portion 191C2 may be located at a lower level than a level of the lower end of the first conductive portion 191C1.

However, according to some example embodiments, the capping pad 147 may be omitted. In this case, the upper surface of the first channel pad 145 may be positioned at substantially the same level as the upper surface of the cell region insulating layer 190 and may contact the lower surface of the insulating pattern 191I.

The second gate electrode 150 may be disposed on the insulating pattern 191I and the conductive pattern 191C. The second gate electrode 150 may be positioned at a higher level than the first channel structures CH1. A first upper insulating layer 192 may be disposed between the second gate electrode 150 and the insulating pattern 191I and the conductive pattern 191C. The second gate electrode 150 may be spaced apart from the insulating pattern 191I by the first upper insulating layer 192. The first upper insulating layer 192 may have a thickness greater than a thickness of the insulating pattern 191I. The first upper insulating layer 192 may include, for example, silicon oxide. A thickness of the second gate electrode 150 may be greater than a thickness of each of the first gate electrodes 130. For example, the thickness of the second gate electrode 150 may be five times greater than the thickness of each of the first gate electrodes 130. In some example embodiments, the second gate electrode 150 may include a material different from a material of the first gate electrodes 130. For example, the second gate electrode 150 may be a semiconductor material layer such as polycrystalline silicon. However, unlike this, the second gate electrode 150 may include at least one of a doped semiconductor material, a metal nitride (e.g., TiN or TaN), and a transition metal (e.g., Ti or Ta).

The second gate electrode 150 may be a string select gate electrode for a string select transistor. In this specification, the second gate electrode 150 may be referred to as an “upper horizontal conductive layer”.

The second to fourth upper insulating layers 193, 194, and 195 may be sequentially stacked on the second gate electrode 150. The second to fourth upper insulating layers 193, 194, and 195 may include at least one of silicon oxide, silicon nitride, and silicon oxynitride.

The upper isolation regions SS may be disposed to pass through the second gate electrode 150 and extend in the X-direction. In some example embodiments, upper surfaces of the upper isolation regions SS may be positioned at substantially the same level as the upper surface of the second gate electrode 150. The upper isolation regions SS may pass through the second gate electrode 150 and may extend into the first upper insulating layer 192. Lower surfaces of the upper isolation regions SS may be positioned at a higher level than a level of the insulating pattern 191I.

The upper isolation regions SS may be located at a higher level than the separation regions MS. In a plan view, at least a portion of the upper isolation regions SS may overlap the separation regions MS extending in the X-direction. A distance between adjacent separation regions MS in the Y-direction may be greater than a distance between adjacent upper isolation regions SS in the Y-direction. Accordingly, in a plan view, at least a portion of the upper isolation regions SS may be disposed between adjacent separation regions MS. As the upper isolation regions SS and the second gate electrode 150 are positioned at a higher level than a level of the separation regions MS and a level of the first channel structures CH1, dummy structures between the first channel structures CH1 may be omitted, and the semiconductor device 100 may have an improved degree of integration.

An upper isolation insulating layer 103 may be disposed in the upper isolation regions SS. In some example embodiments, the upper isolation insulating layer 103 may include an insulating material such as silicon oxide. However, according to some example embodiments, the upper isolation regions SS may include at least a portion of materials of the second channel structures CH2.

The second channel structures CH2 may pass through the second gate electrode 150 and be connected to the conductive pattern 191C. The second channel structures CH2 may be electrically connected to respective ones of the first channel structures CH1 through the conductive patterns 191C. The second channel structures CH2 may be string select channel structures of string select transistors. Each of the second channel structures CH2 may have a columnar shape and may have an inclined side surface that becomes narrower closer to the substrate 101 according to an aspect ratio.

The second channel structures CH2 may be spaced apart from each other while forming rows and columns on the insulating pattern 191I and the conductive pattern 191C. The second channel structures CH2 may be disposed to form a lattice pattern in an X-Y plane or may be disposed in a zigzag shape in one direction. At least a portion of the second channel structures CH2 may include a portion that does not overlap with the first channel structures CH1 in the Z-direction. Referring to FIG. 1B, at least a portion of the first channel structures CH1 may include a first area overlapping the second channel structures CH2 in the Z-direction and a remaining second area.

Each of the second channel structures CH2 may further include, in addition to the second channel layer 170, a second dielectric layer 172, a second filling insulating layer 174 between the second channel layers 170, a semiconductor spacer layer 171, and a second channel pad 175 on an upper end of the second filling insulating layer 174.

The second channel layer 170 may be formed in an annular shape surrounding the second filling insulating layer 174 therein, but according to some example embodiments, may have a pillar shape such as a cylinder or a prism without the second filling insulating layer 174. The second channel layer 170 may be connected to the conductive pattern 191C on the lower portion thereof. The second channel layer 170 may include a semiconductor material such as polycrystalline silicon or single crystal silicon, and the semiconductor material may be an undoped material or a material containing p-type or n-type impurities.

The second dielectric layer 172 may be disposed between the second gate electrode 150 and the second channel layer 170. In some example embodiments, the second dielectric layer 172 may include a different structure or a different material from the first dielectric layer 142. For example, the first dielectric layer 142 may have a multilayer structure and the second dielectric layer 172 may have a single layer structure. The second dielectric layer 172 may have a single layer structure including silicon oxide, silicon nitride, silicon oxynitride, or a high-k dielectric material.

The semiconductor spacer layer 171 may be a layer covering a portion of an outer surface of the second channel layer 170. The semiconductor spacer layer 171 may have a conformal thickness and may extend between the second dielectric layer 172 and the second channel layer 170. The lower end of the semiconductor spacer layer 171 is positioned at a level higher than a level of the insulating pattern 191I, and the second dielectric layer 172 may contact the second channel layer 170 while covering the lower end of the semiconductor spacer layer 171. In some example embodiments, the lower end of the semiconductor spacer layer 171 may be located at a level lower than a level of the lower surface of the second gate electrode 150, but according to some example embodiments, may be located on substantially the same level as the lower surface of the second gate electrode 150.

The semiconductor spacer layer 171 may be a spacer structure for an anisotropic etching operation used to form the conductive pattern 191C, and may serve as a channel layer together with the second channel layer 170. The semiconductor spacer layer 171 may include a semiconductor material such as silicon. For example, when the semiconductor spacer layer 171 and the second channel layer 170 include the same material, the interface between the two components may not be distinguished. However, according to some example embodiments, the semiconductor spacer layer 171 may be omitted or may be replaced with a separate spacer layer other than a semiconductor.

The second channel pad 175 may cover the upper surface of the second filling insulating layer 174 and be electrically connected to the second channel layer 170. The second channel pad 175 may be disposed on the second channel layer 170. The second channel pad 175 may include, for example, polycrystalline silicon.

Each of the second channel structures CH2 may include a first portion CH2_P1 penetrating through the second gate electrode 150, a second portion CH2_P2 on the first portion CH2_P1, and a third portion CH2_P3 below the first portion CH2_P1. The first to third portions CH2_P1, CH2_P2, and CH2_P3 may be integrally connected.

Each of the second channel structures CH2 may further include a bent portion CH2_BP defined by the first portion CH2_P1 and the second portion CH2_P2. The bent portion CH2_BP may be positioned at a level adjacent to the upper surface of the second gate electrode 150. The second portion CH2_P2 may be positioned at a level higher than a level of the second gate electrode 150. Referring to FIG. 1B, the first portion CH2_P1 may have a first width w1, and the second portion CH2_P2 may have a second width w2 greater than the first width w1. For example, the second channel structures CH2 may include an upper second portion CH2_P2 having a larger planar area than a planar area of the lower first portion CH2_P1. Accordingly, a difficulty for forming the upper interconnection structure 180 may be reduced, and the semiconductor device 100 may have improved reliability. For example, as a process margin for forming a stud 181 in contact with the second channel structures CH2 of the upper interconnection structure 180 is secured, productivity and/or electrical characteristics of the semiconductor device may be improved.

In some example embodiments, the second width w2 of the second portion CH2_P2 may be greater than the width of the first channel structures CH1.

The second portion CH2_P2 may cover a portion of the upper surface of the second gate electrode 150. The second dielectric layer 172 covers the side surface of the second gate electrode 150 in the first portion CH2_P1, and extends from the side surface of the second gate electrode 150 in the second portion CH2_P1 to cover a portion of the upper surface of the second gate electrode 150.

An upper surface of the second portion CH2_P2 may be positioned at a higher level than a level of respective upper surfaces of the upper isolation regions SS. Upper surfaces of the upper isolation regions SS may be positioned between the first portion CH2_P1 and the second portion CH2_P2 or at a level adjacent to the bent portion CH2_BP.

The third portion CH2_P3 may have a third width greater than the first width w1 of the first portion CH2_P1. The third portion CH2_P3 may cover a portion of the lower surface of the second gate electrode 150. The second dielectric layer 172 covers the side surface of the second gate electrode 150 in the first portion CH2_P1 and extends from the side surface of the second gate electrode 150 in the third portion CH2_P3 to cover a portion of the lower surface of the second gate electrode 150. The semiconductor spacer layer 171 may be disposed between the second channel layer 170 and the second dielectric layer 172 in the first portion CH2_P1 and the second portion CH2_P2, and the second channel layer 170 may contact the second dielectric layer 172 within the third portion CH2_P3.

In this specification, the second channel structures CH2 may be referred to as “vertical semiconductor structures”.

The upper interconnection structure 180 may include a conductive material and may be electrically connected to the first and second channel structures CH1 and CH2. The upper interconnection structure 180 may include studs 181, contact plugs 182, and an upper interconnection 183. The studs 181 may pass through the third upper insulating layer 194 and contact the upper surface of the second portion CH2_P2. Process defects such as separation between the second channel structures CH2 and the studs 181 may be reduced by the second portion CH2_P2 having a larger planar area than a planar area of the first portion CH2_P1. Referring to FIG. 1B, the studs 181 may be respectively formed to have a larger width than a width of the first portion CH2_P1 by the second portion CH2_P2, but this is to describe some example embodiments of the studs 181. Therefore, the studs 181 may have substantially the same width as the first portion CH2_P1 or may have a smaller width than the width of the first portion CH2_P1. The contact plugs 182 may pass through the fourth upper insulating layer 195 and may be connected to the studs 181. The upper interconnection 183 may be disposed on the contact plugs 182 and the fourth upper insulating layer 195. A portion of the upper interconnection 183 may be bit lines contacting the contact plugs 182. As illustrated in FIGS. 1B and 2, the bit lines may extend in a direction perpendicular to the direction in which the upper isolation regions SS extend. The bit lines may be electrically connected to the second channel structures CH2 through contact plugs 182.

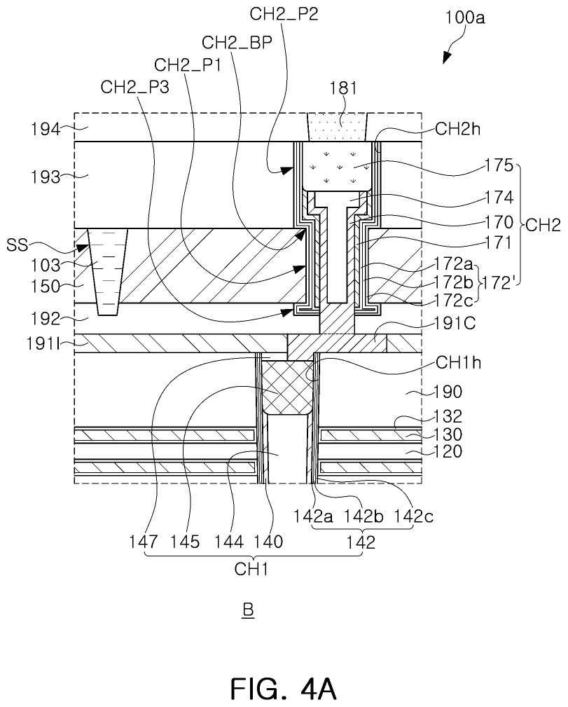

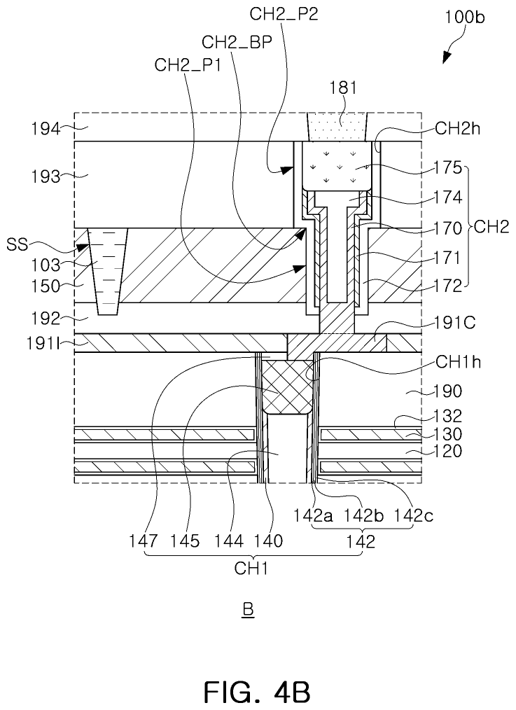

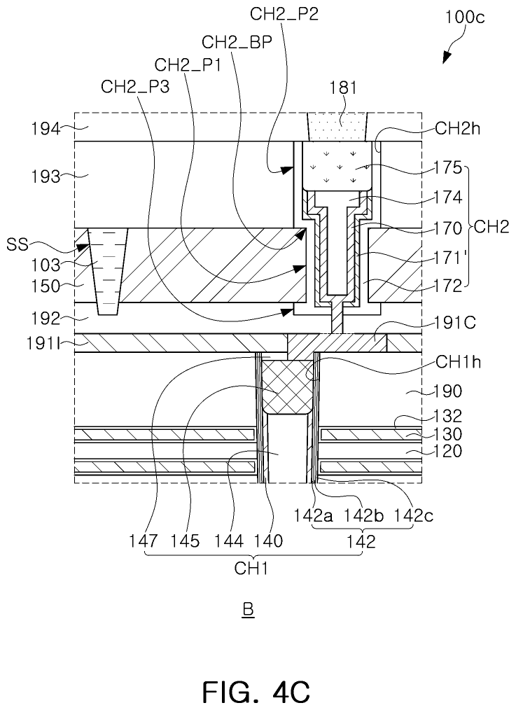

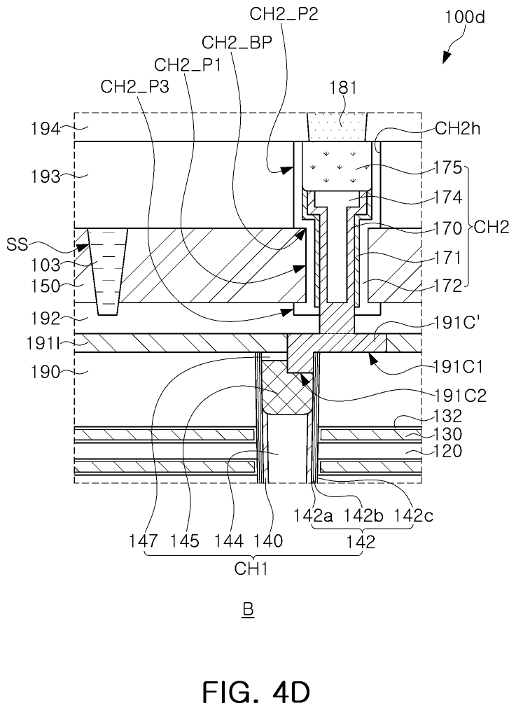

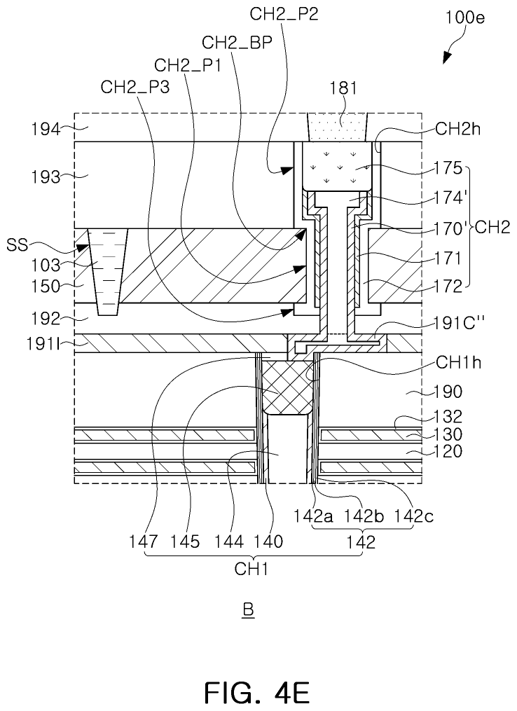

FIGS. 4A to 4E are partial enlarged views illustrating a semiconductor device according to some example embodiments. FIGS. 4A to 4E illustrate an area corresponding to the area ‘B’ of FIG. 2.

Referring to FIG. 4A, in a semiconductor device 100a, the second channel structures CH2 may include a second dielectric layer 172′ of a multilevel/multilayer structure. The second dielectric layer 172′ may include a tunneling layer 172a, a charge storage layer 172b, and a blocking layer 172c sequentially stacked on the second channel layer 170. The tunneling layer 172a may tunnel charges into the charge storage layer 172b, and may include, for example, silicon oxide (SiO₂), silicon nitride (Si₃N₄), silicon oxynitride (SiON), or combinations thereof. The charge storage layer 172b may be a charge trap layer or a floating gate conductive layer. The blocking layer 172c may include silicon oxide (SiO₂), silicon nitride (Si₃N₄), silicon oxynitride (SiON), a high-k dielectric material, or combinations thereof. The tunneling layer 172a, the charge storage layer 172b, and the blocking layer 172c of the second dielectric layer 172′ may include the same material as the material of the tunneling layer 142a, the charge storage layer 142b, and the blocking layer 142c of the first dielectric layer 142 respectively, but present inventive concepts are not limited thereto.

Referring to FIG. 4B, in a semiconductor device 100b, the second channel structures CH2 may not include the third portion CH2_P3. For example, each of the second channel structures CH2 includes a first portion CH2_P1 having a first width w1 (see FIG. 1B) and a second portion CH2_P2 having a second width w2 (see FIG. 1B) greater than the first width w1, but may not include a region having a larger width than the width of the first portion CH2_P1, below the first portion CH2_P1. Accordingly, the second channel structures CH2 may not partially cover the lower surface of the second gate electrode 150, which may be a structure due to material characteristics or process conditions of the first upper insulating layer 192.

Referring to FIG. 4C, in a semiconductor device 100c, the semiconductor spacer layer 171′ may include a horizontal extension as well as a vertical extension. An upper surface of the horizontal extension may contact the second channel layer 170, and a lower surface of the horizontal extension may contact the second dielectric layer 172, which may be a structure formed by etching only a portion of the bottom surface of the opening using an anisotropic etching operation to form the conductive pattern 191C. Accordingly, a portion of the second channel layer 170 extending from the bottom of the second dielectric layer 172 toward the conductive pattern 191C may have a relatively reduced width, compared to FIG. 3.

Referring to FIG. 4D, in a semiconductor device 100d, the conductive pattern 191C′ may extend into the first channel pad 145. The conductive pattern 191C′ may include a first conductive portion 191C1 on the cell region insulating layer 190 and a second conductive portion 191C2 on the first channel pad 145. As the conductive pattern 191C′ extends into the first channel pad 145, the lower end of the second conductive portion 191C2 may be positioned at a lower level than a level of the lower surface of the capping pad 147, which may be because part of the first channel pad 145 is removed along with the capping pad 147 in an etching operation used to form the conductive pattern 191C′.

Referring to FIG. 4E, in a semiconductor device 100e, the second filling insulating layer 174′ may include a portion extending into the conductive pattern 191C″. In some example embodiments, the second channel layer 170 and the conductive pattern 191C may be integrally connected and formed of an extended conductive material layer, and the conductive material layer may have a conformal thickness. However, according to some example embodiments, the shape of the conductive material layer may be variously changed, such as a shape having a larger thickness in a specific region or a closed space, unlike that illustrated in FIG. 4E.

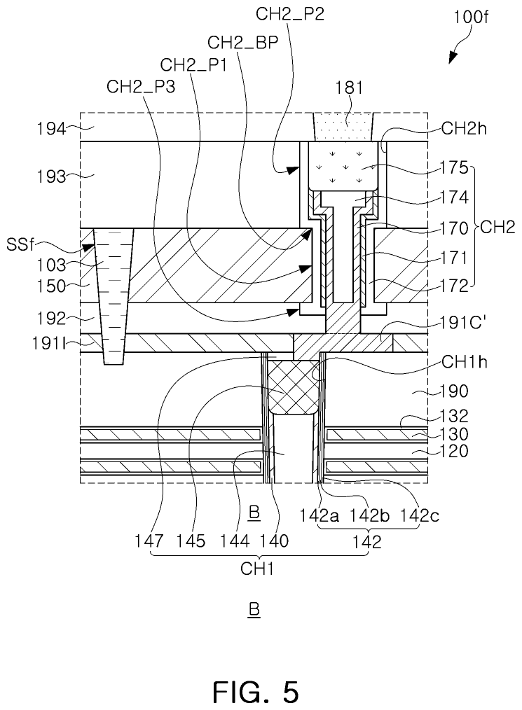

FIG. 5 is an enlarged view of a semiconductor device according to some example embodiments. FIG. 5 illustrates an area corresponding to area ‘B’ in FIG. 2.

Referring to FIG. 5, in a semiconductor device 100f, lower ends of upper isolation regions SSf may be positioned at a level lower than a level of the upper surface of the first channel structure CH1. The upper isolation regions SSf may pass through the first upper insulating layer 192 and the insulating pattern 191I. The upper isolation regions SSf may extend into the cell region insulating layer 190 or may extend into the separation regions MS from other regions. However, even in this case, the lower ends of the upper isolation regions SSf may be positioned at a level higher than a level of the first gate electrode 130 disposed on the uppermost portion and may be spaced apart from the first gate electrodes 130.

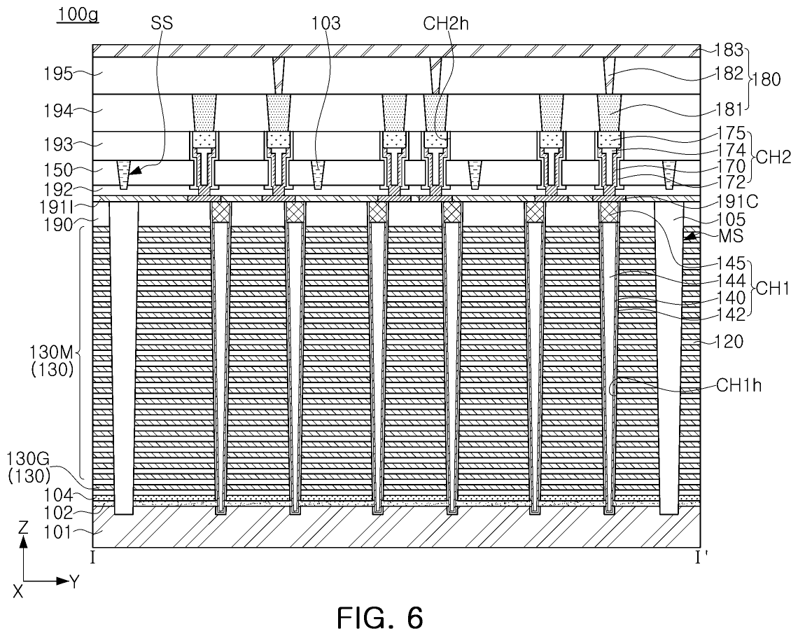

FIG. 6 is a schematic cross-sectional view of a semiconductor device according to some example embodiments. FIG. 6 illustrates a region corresponding to a section taken along line I-I′ of FIG. 1.

Referring to FIG. 6, in a semiconductor device 100g, at least one first channel structure CH1 among the first channel structures CH1 may completely overlap the second channel structures CH2 in the Z-direction. For example, the semiconductor device 100g may include a first channel structure CH1 having the same central axis as the central axis of the second channel structure CH2 in a plan view. The first channel structure CH1 may be a structure disposed in a region adjacent to the separation regions MS among the first channel structures CH1.

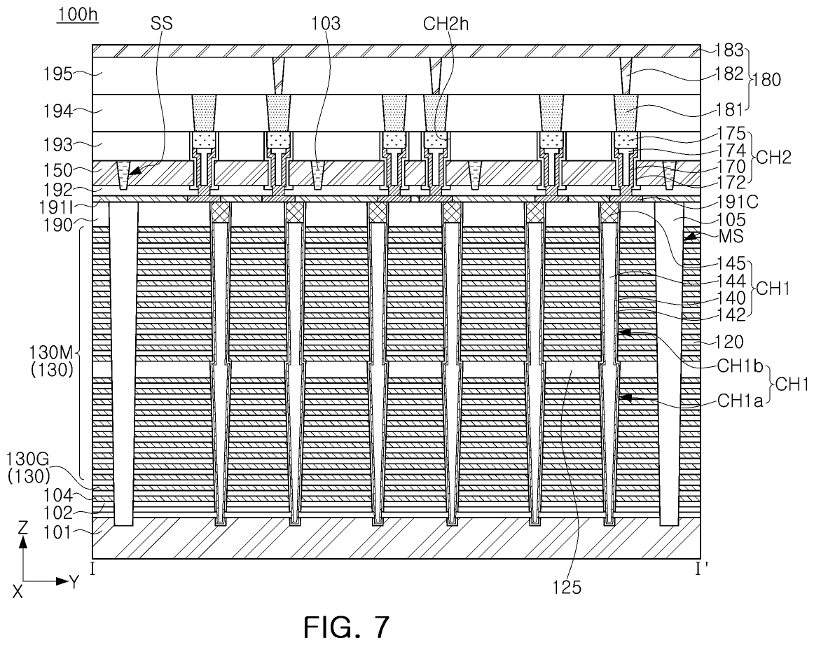

FIG. 7 is a schematic cross-sectional view of a semiconductor device according to some example embodiments. FIG. 7 illustrates a region corresponding to a section taken along line I-I′ of FIG. 1.

Referring to FIG. 7, in a semiconductor device 100h, the stack structure of the first gate electrodes 130 is formed of lower and upper stack structures that are vertically stacked, and the first channel structures CH1 may be formed of lower and upper channel structures CH1a and CH1b stacked vertically. Such a structure of the first channel structures CH1 may be introduced to stably form the first channel structures CH1 when the number of the relatively stacked first gate electrodes 130 is increased. According to some example embodiments, the number of stacked first channel structures may be variously changed.

The first channel structures CH1 may have a shape in which the lower channel structures CH1a and the upper channel structures CH1b are connected, and may have a bent portion due to a difference in width in the connection region. The first channel layer 140, the first dielectric layer 142, and the first filling insulating layer 144 may be connected to each other between the lower channel structure CH1a and the upper channel structure CH1b. The first channel pad 145 may be disposed only on an upper end of the upper channel structure CH1b. However, according to some example embodiments, the lower channel structure CH1a and the upper channel structure CH1b may each include a first channel pad 145. In this case, the first channel pad 145 of the lower channel structure CH1a may be connected to the first channel layer 140 of the upper channel structure CH1b. An upper interlayer insulating layer 125 having a relatively thick thickness may be disposed on the uppermost part of the lower stack structure. However, the shapes of the interlayer insulating layers 120 and the upper interlayer insulating layer 125 may be variously changed in some example embodiments. In this manner, the shape of the plurality of stacked first channel structures CH1 may also be applied to the embodiments of FIGS. 1A to 6, 8A, and 8B.

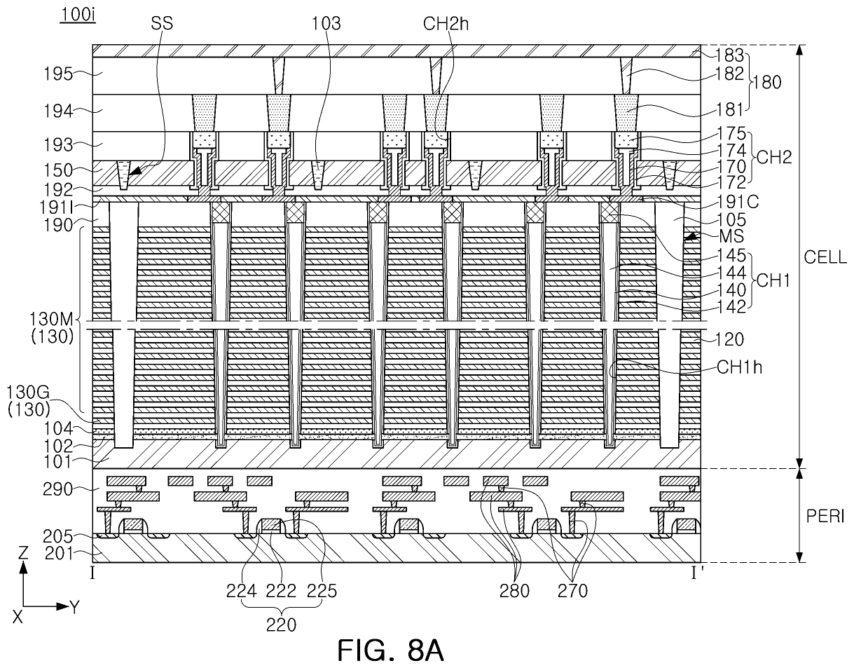

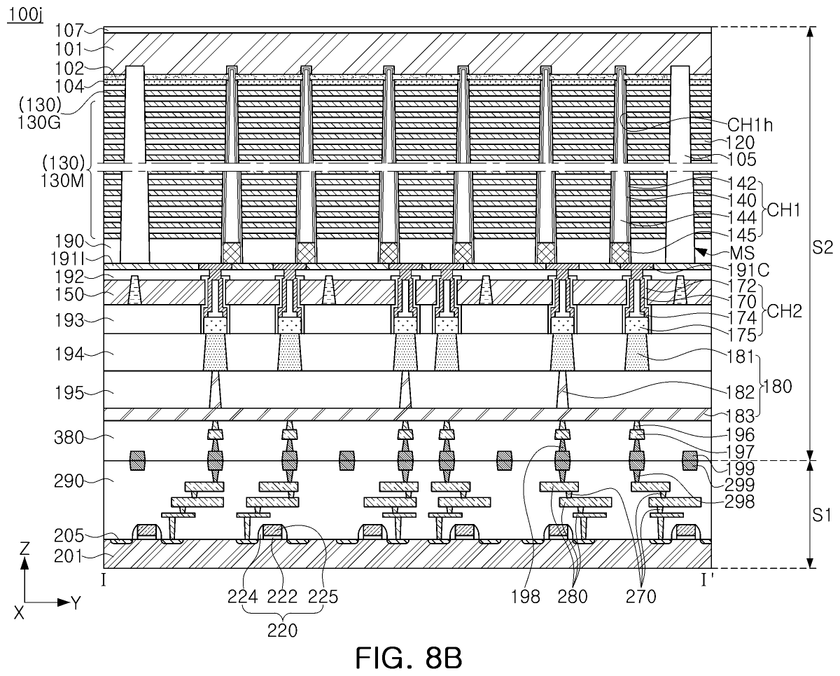

FIGS. 8A and 8B are schematic cross-sectional views of a semiconductor device according to some example embodiments. FIGS. 8A and 8B illustrate a region corresponding to a section taken along line I-I′ of FIG. 1.

Referring to FIG. 8A, a semiconductor device 100i may include a memory cell area CELL and a peripheral circuit area PERI stacked vertically. The memory cell area CELL may be disposed on an upper end of the peripheral circuit area PERI. For example, in the case of the semiconductor device 100 of FIG. 2, the peripheral circuit area PERI is disposed on the substrate 101 in an area not illustrated, or, as in the semiconductor device 100i of the present embodiment, the peripheral circuit area PERI may be disposed on the lower portion. In some example embodiments, the memory cell area CELL may be disposed below the peripheral circuit area PERI. Description of the memory cell area CELL may be equally applied to the description of FIGS. 1A to 3.

The peripheral circuit area PERI may include a base substrate 201, circuit elements 220 disposed on the base substrate 201, circuit contact plugs 270, and circuit wiring lines 280.

The base substrate 201 may have an upper surface extending in the X and Y-directions. The base substrate 201 may have separate device isolation layers formed thereon to define an active region. Source/drain regions 205 containing impurities may be disposed in a portion of the active region. The base substrate 201 may include a semiconductor material, for example, a group IV semiconductor, a group III-V compound semiconductor, or a group II-VI compound semiconductor. The base substrate 201 may be provided as a bulk wafer or an epitaxial layer. In embodiments of FIG. 8A, the upper substrate 101 may be provided with a polycrystalline semiconductor layer such as a polycrystalline silicon layer or an epitaxial layer.

The circuit elements 220 may include planar transistors. Each of the circuit elements 220 may include a circuit gate dielectric layer 222, a spacer layer 224 and a circuit gate electrode 225. The source/drain regions 205 may be disposed in the base substrate 201 on both sides of the circuit gate electrode 225.

A peripheral region insulating layer 290 may be disposed on the circuit element 220, on the base substrate 201. The circuit contact plugs 270 may pass through the peripheral region insulating layer 290 and be connected to the source/drain regions 205. Electrical signals may be applied to the circuit element 220 through the circuit contact plugs 270. In an area not illustrated, the circuit contact plugs 270 may also be connected to the circuit gate electrode 225. The circuit wiring lines 280 may be connected to the circuit contact plugs 270 and may be disposed as a plurality of layers.

In a semiconductor device 100i, the peripheral circuit area PERI may be fabricated first, and then, the substrate 101 of the memory cell area CELL may be formed thereon to form the memory cell area CELL. The substrate 101 may have the same size as the base substrate 201 or may be smaller than the base substrate 201. The memory cell area CELL and the peripheral circuit area PERI may be connected to each other in an area not illustrated. For example, one end of the gate electrode 130 in the Y-direction may be electrically connected to the circuit elements 220. In this manner, the form in which the memory cell area CELL and the peripheral circuit area PERI are vertically stacked may also be applied to the embodiments of FIGS. 1A to 7.

Referring to FIG. 8B, a semiconductor device 100j may include a first structure Si and a second structure S2 bonded by a wafer bonding method.

The description of the peripheral circuit area PERI described above with reference to FIG. 8A may be applied to the first structure S1. However, the first structure S1 may further include first bonding vias 298 and first bonding pads 299 that are bonding structures. The first bonding vias 298 may be disposed above the uppermost circuit wiring lines 280 and may be connected to the circuit wiring lines 280. At least some of the first bonding pads 299 may be connected to the first bonding vias 298, on the first bonding vias 298. The first bonding pads 299 may be connected to the second bonding pads 199 of the second structure S2. The first bonding pads 299 together with the second bonding pads 199 may provide an electrical connection path according to bonding of the first structure S1 and the second structure S2. The first bonding vias 298 and the first bonding pads 299 may include a conductive material, such as copper (Cu).

Regarding the second structure S2, unless otherwise described, descriptions with reference to FIGS. 1A to 3 may be equally applied. The upper interconnection structure of the second structure S2 may further include a conductive via 196 and a conductive line 197 connected to the upper interconnection 183. The conductive line 197 may include a plurality of conductive lines disposed at different levels unlike those illustrated. In addition, the second structure S2 may further include second bonding vias 198 and second bonding pads 199 that are bonding structures. The second structure S2 may further include a protective layer 107 covering an upper surface of the substrate 101.

The second bonding vias 198 and the second bonding pads 199 may be disposed below the lowermost conductive line 197. The second bonding vias 198 are connected to the conductive line 197 and the second bonding pads 199, and the second bonding pads 199 may be connected to and combined with the first bonding pads 299 of the first structure S1. The second bonding vias 198 and the second bonding pads 199 may include a conductive material, such as copper (Cu).

The first structure S1 and the second structure S2 may be bonded by copper (Cu)-copper (Cu) bonding using the first bonding pads 299 and the second bonding pads 199. In addition to the copper (Cu)-copper (Cu) bonding, the first structure S1 and the second structure S2 may be additionally bonded by dielectric-dielectric bonding. The dielectric-dielectric bonding may be bonding by dielectric layers that form a portion of each of the peripheral region insulating layer 290 and a bonding insulating layer 380 and respectively surround the first bonding pads 299 and the second bonding pads 199. Accordingly, the first structure S1 and the second structure S2 may be bonded without a separate adhesive layer.

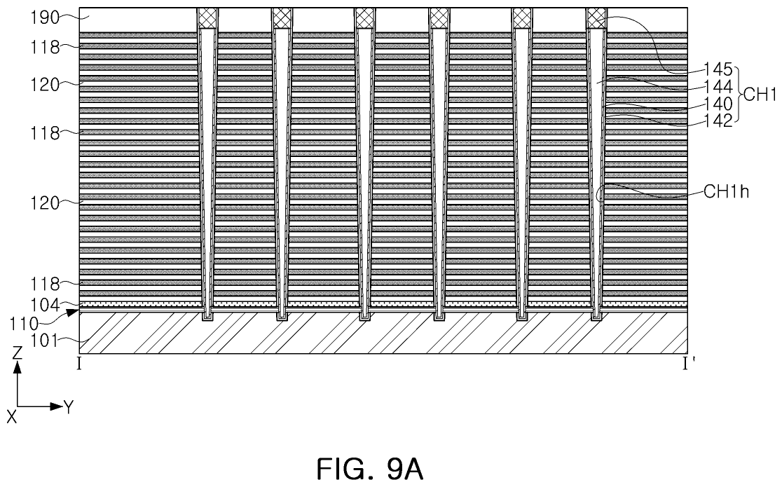

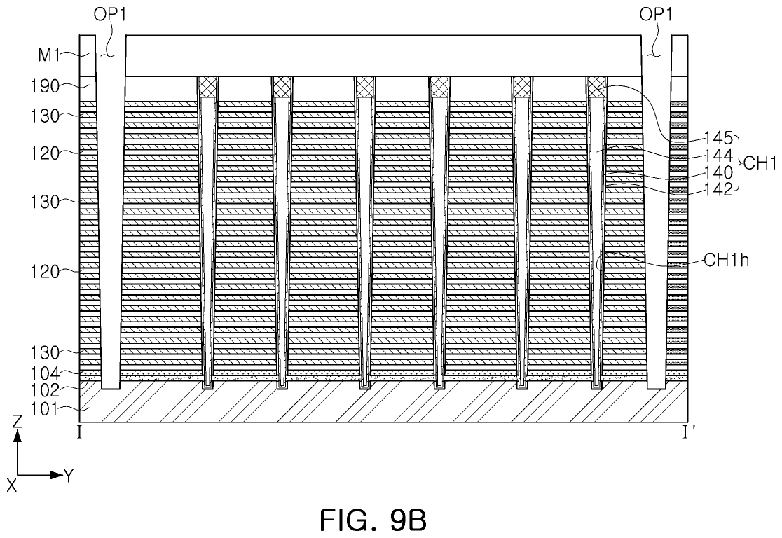

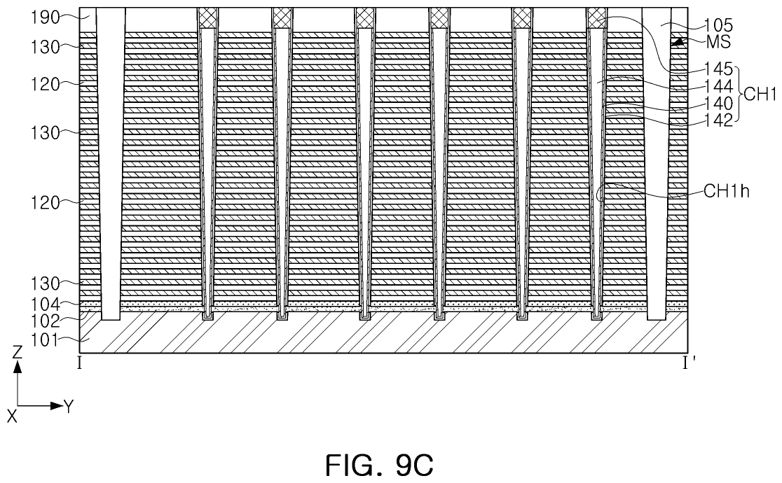

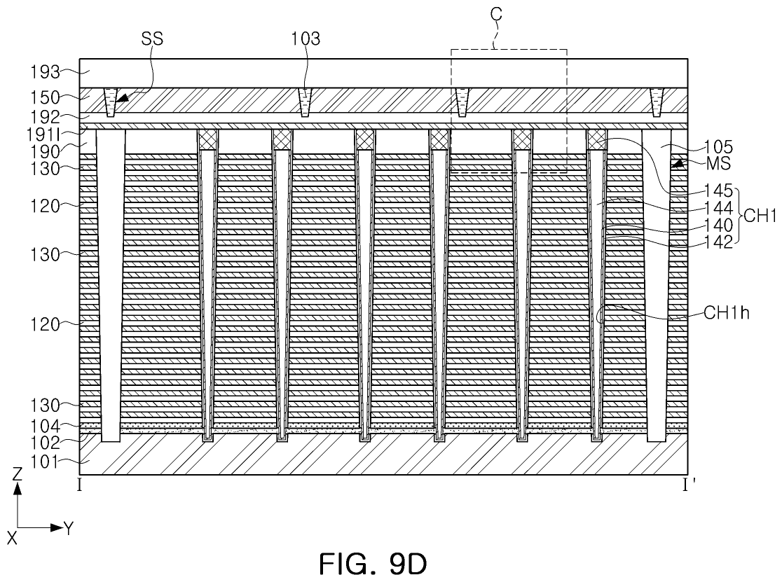

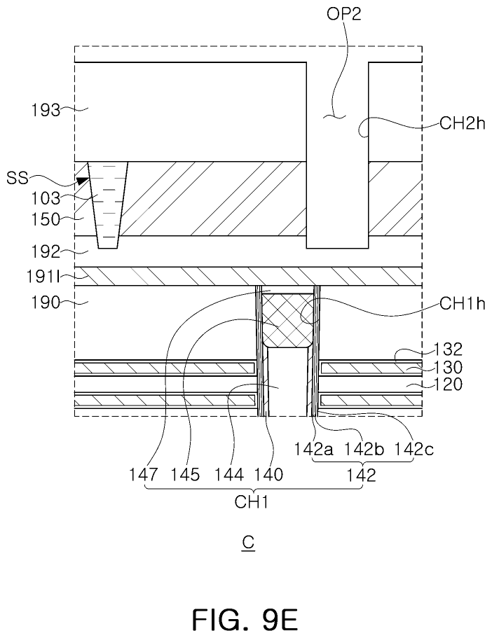

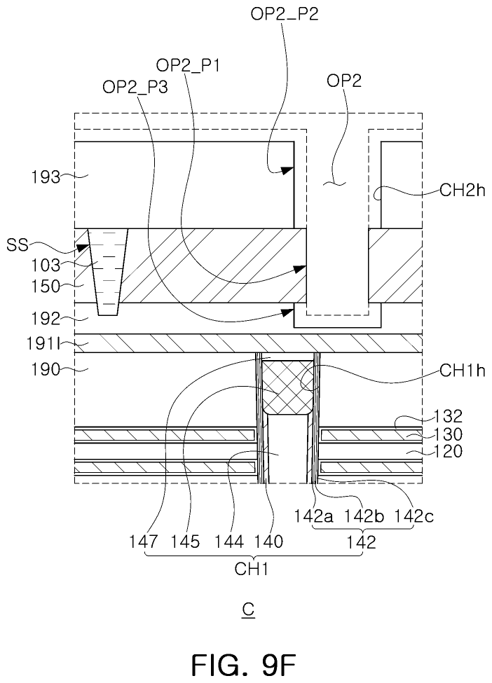

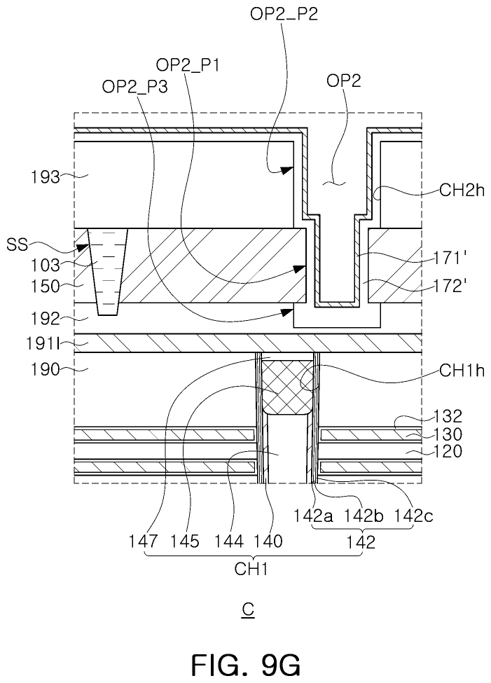

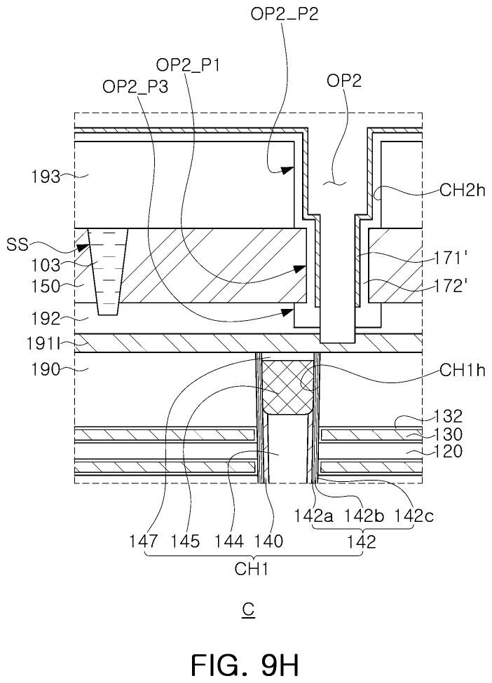

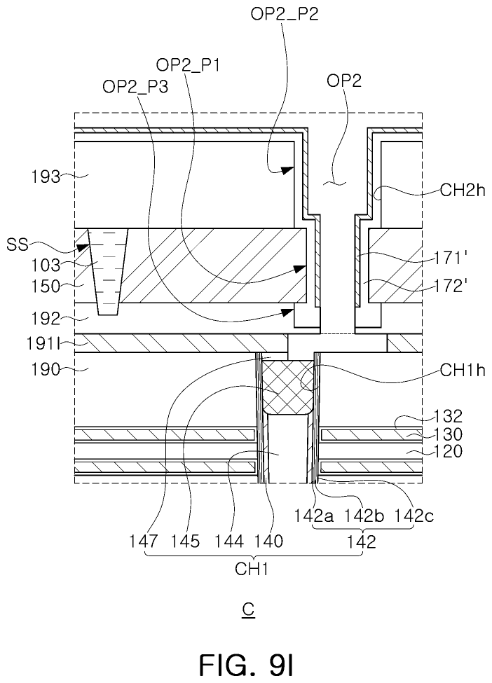

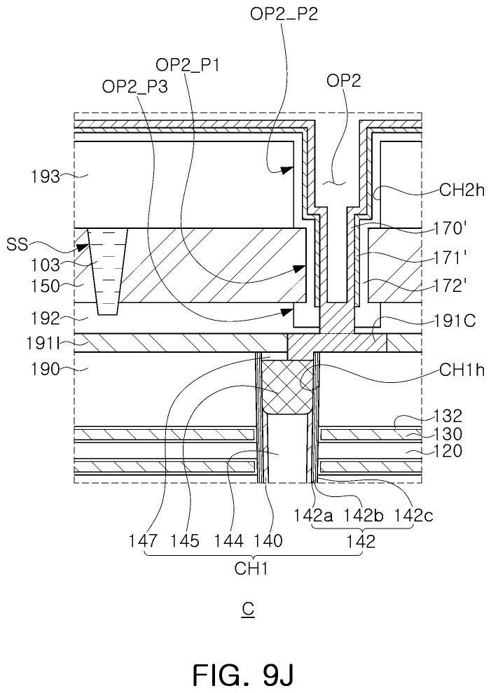

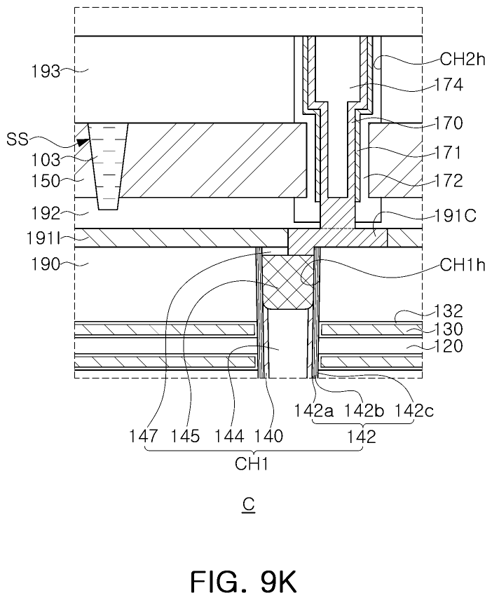

FIGS. 9A to 9K are schematic cross-sectional views and partially enlarged views illustrating a method of manufacturing a semiconductor device according to some example embodiments. In FIGS. 9A to 9D, areas corresponding to the area illustrated in FIG. 2 are illustrated, and in FIGS. 9E to 9K, areas corresponding to the area ‘C’ in FIG. 9D are illustrated.

Referring to FIG. 9A, horizontal sacrificial layers 110 and a second horizontal conductive layer 104 are formed on a substrate 101, and sacrificial insulating layers 118 and interlayer insulating layers 120 are alternately stacked, and first channel structures CH1 may be formed.

The horizontal sacrificial layers 110 may include first to third horizontal sacrificial layers sequentially formed on the substrate 101. The second horizontal sacrificial layer may include a material different from a material of the first horizontal sacrificial layer and the third horizontal sacrificial layer. The horizontal sacrificial layers 110 may be layers replaced with the first horizontal conductive layer 102 (see FIG. 2) using a subsequent operation. For example, the first and third horizontal sacrificial layers may be formed of the same material as the interlayer insulating layers 120, and the second horizontal sacrificial layer may be formed of the same material as the sacrificial insulating layers 118. The second horizontal conductive layer 104 may be formed on the horizontal sacrificial layers 110.

Some of the sacrificial insulating layers 118 may be replaced with first gate electrodes 130 (see FIG. 2) through a subsequent operation. The sacrificial insulating layers 118 may be formed of a material different from a material of the interlayer insulating layers 120, and may be formed of a material that may be etched with etch selectivity with respect to the interlayer insulating layers 120 under specific etching conditions. For example, the interlayer insulating layer 120 may be formed of at least one of silicon oxide and silicon nitride, and the sacrificial insulating layers 118 may be formed of a material different from the material of the interlayer insulating layer 120, which is selected from silicon, silicon oxide, silicon carbide, and/or silicon nitride. In some embodiments, the interlayer insulating layers 120 may not all have the same thickness. The thicknesses of the interlayer insulating layers 120 and the sacrificial insulating layers 118 and the number of layers constituting the same may be variously changed from those illustrated.

Next, a portion of the cell region insulating layer 190 covering the stack structure of the sacrificial insulating layers 118 and the interlayer insulating layers 120 may be formed, and openings corresponding to the first channel holes CH1h may be formed. The first channel holes CH1h may be formed in a hole shape by anisotropically etching the sacrificial insulating layers 118 and the interlayer insulating layers 120 using a mask layer. Due to the height of the stack structure, sidewalls of the resulting first channel holes CH1h may not be perpendicular with respect to the upper surface of the substrate 101. The first channel holes CH1h may be formed to recess portions of the substrate 101. Next, a first dielectric layer 142, a first channel layer 140, a first filling insulating layer 144, and a first channel pad 145 may be sequentially formed in/on the first channel holes CH1h. The first dielectric layer 142 may be formed to have a uniform thickness using an atomic layer deposition ALD operation or a chemical vapor deposition CVD operation. The first channel layer 140 may be formed on the first dielectric layer 142 within the first channel structures CH1. The first filling insulating layer 144 is formed to fill the first channel structures CH1 and may be formed of an insulating material. The first channel pad 145 may be formed of a conductive material, for example, polycrystalline silicon.

Referring to FIG. 9B, first openings OP1 penetrating through the stack structure of the sacrificial insulating layers 118 and the interlayer insulating layers 120 may be formed in regions corresponding to the separation regions MS (see FIG. 2), the first horizontal conductive layer 102 and the first gate electrodes 130 may be formed.

First, a mask layer M1 may be formed on the first channel structures CH1, and the first openings OP1 may be formed. The first openings OP1 may be formed to extend in the X-direction by penetrating through the stack structure of the sacrificial insulating layers 118 and the interlayer insulating layers 120 and penetrating through the second horizontal conductive layer 104 in the lower portion thereof. Next, while forming separate sacrificial spacer layers in the first openings OP1, the second horizontal sacrificial layer may be exposed using an etch-back operation. The exposed second horizontal sacrificial layer may be selectively removed, and then the upper and lower first and third horizontal sacrificial layers may be removed. The horizontal sacrificial layers 110 may be removed using, for example, a wet etching operation. During the operation of removing the horizontal sacrificial layers 110, a portion of the first dielectric layer 142 is exposed in the region where the horizontal sacrificial layers 110 are removed, and this exposed portion of the first dielectric layer 142 may also be removed. After forming the first horizontal conductive layer 102 by depositing a conductive material in the region from which the horizontal sacrificial layers 110 are removed, the sacrificial spacer layers may be removed in the first openings OP1. Next, tunnel portions may be formed by removing the sacrificial insulating layers 118 exposed by the first openings OP1, and first gate electrodes 130 are formed by filling the tunnel portions with a conductive material. The tunnel portions may be formed, for example, using a wet etching operation to selectively remove the sacrificial insulating layers 118 with respect to the interlayer insulating layers 120. The conductive material constituting the first gate electrodes 130 may include metal, polycrystalline silicon, or a metal silicide material. In this operation, before forming the first gate electrodes 130, a dielectric layer having a conformal thickness may be deposited to form the gate dielectric layer 132 (see FIG. 3). Next, the first openings OP1 may be formed again by removing the conductive material.

In some example embodiments, when the conductive material is removed, portions of the first gate electrodes 130 from the first openings OP1 may be removed together. The first gate electrodes 130 may include regions partially recessed from the first openings OP1, compared to the interlayer insulating layers 120.

Referring to FIG. 9C, an isolation insulating layer 105 may be formed in the separation regions MS.

The isolation insulating layer 105 may be formed by filling the first openings OP1 with an insulating material and performing a planarization operation to remove the insulating material and the mask layer M1. The insulating material may include silicon oxide, silicon nitride, or silicon oxynitride. According to some example embodiments, the first openings OP1 may be filled with a conductive material together with the insulating material.

The planarization operation may be performed so that upper surfaces of the isolation insulating layer 105 in the separation regions MS are positioned at substantially the same level as upper surfaces of the first channel structures CH1.

Referring to FIG. 9D, an upper isolation insulating layer 103 may be formed in the second gate electrode 150 and the upper isolation regions SS.

An insulating pattern 191I, a first upper insulating layer 192, a second gate electrode 150, a second upper insulating layer 193 may be sequentially formed using a deposition operation, on the separation regions MS, the first channel structures CH1, and the cell region insulating layer 190.

The insulating pattern 191I may include a material different from a material of the cell region insulating layer 190 and/or different from the first upper insulating layer 192. For example, the insulating pattern 191I may include silicon nitride. The insulating pattern 191I may be a plate layer having a conformal thickness and extending in the X and Y-directions. The first upper insulating layer 192 may be formed to have a greater thickness than a thickness of the insulating pattern 191I. The second gate electrode 150 may be formed by depositing a conductive material, for example, doped polycrystalline silicon. The second gate electrode 150 may be formed to have a thickness greater than the thickness of each of the first gate electrodes 130.

Trenches may expose the first upper insulating layer 192 by penetrating through the second gate electrode 150. These trenches may be formed to form regions corresponding to the upper isolation regions SS, and an insulating material may be deposited in the trenches, and the upper isolation insulating layer 103 may be formed by performing the planarization operation.

Referring to FIG. 9E, second openings OP2 may be formed.

The second openings OP2 penetrating through the second upper insulating layer 193 may be formed by performing a patterning operation using the second upper insulating layer 193 as a mask. The second openings OP2 may expose the first upper insulating layer 192. The second openings OP2 may be formed as a plurality of circular holes, and each may include a portion that does not overlap and a portion that does overlap the first channel structures CH1 in a plan view. In an example embodiment, a portion of the first upper insulating layer 192 is removed using the patterning operation, and the first upper insulating layer 192 includes portions recessed by the second openings OP2. However, according to some example embodiments, the first upper insulating layer 192 may not be removed and the upper surface of the first upper insulating layer 192 may be exposed.

Referring to FIG. 9F, the first to third opening portions OP2_P1, OP2_P2, and OP_P3 may be formed by partially removing the first and second upper insulating layers 192 and 193 exposed through the second opening OP2.

The first opening portion OP2_P1 corresponds to the first portion CH2_P1 (see FIG. 3), the second opening portion OP_P2 corresponds to the second portion CH2_P2 (see FIG. 3), and the third opening portion OP_P3 may correspond to the third portion CH2_P3 (refer to FIG. 3).

A portion of the second upper insulating layer 193 exposed through the second openings OP2 is removed by performing an etching operation to selectively remove the second upper insulating layer 193 with respect to the second gate electrode 150. Thus, the second opening portion OP2_P2 may be formed. The second opening portion OP2_P2 may pass through the second upper insulating layer 193. As a result, the second opening portion OP2_P2 having a width greater than the width of the first opening portion OP2_P1 penetrating through the second gate electrode 150 may be formed. The etching operation may include, for example, a wet etching operation using HF (hydrofluoric acid). As the second opening portion OP2_P2 having a width greater than the width of the first opening portion OP2_P1 is formed, a difficulty of forming the stud 181 (see FIG. 3) formed through a subsequent operation may be reduced. As a process margin for forming the stud 181 is secured, the stud 181 having a relatively large width may be formed.

In the etching operation, the third opening portion OP3_P3 may be formed by selectively removing a portion of the first upper insulating layer 192 with respect to the second gate electrode 150. For example, in the etching operation, a portion of the first upper insulating layer 192 together with the second upper insulating layer 193 may be removed, which may be because the first upper insulating layer 192 includes the same material as the second upper insulating layer 193. Accordingly, the third opening portion OP2_P3 having a greater width than the width of the first opening portion OP2_P1 may be formed below the first opening portion OP2_P1. In some example embodiments, by using the etching operation performed as an isotropic etching operation, a portion of the first upper insulating layer 192 removed in a horizontal direction and a portion of the first upper insulating layer 192 removed in a vertical direction may be substantially the same or similar.

A portion of the upper surface of the second gate electrode 150 may be exposed by the second opening portion OP2_P2, and a portion of the lower surface of the second gate electrode 150 may be exposed by the third opening portion OP2_P3.

Referring to FIG. 9G, a second dielectric layer 172′ and a semiconductor spacer layer 171′ may be formed in the second opening OP2.

Deposition operations may be sequentially performed to form the second dielectric layer 172′ and the semiconductor spacer layer 171′ conformally covering the sidewall and the bottom surface of the second opening OP2. The second dielectric layer 172′ may be formed as a single layer as illustrated in FIG. 9G, but may be formed as a multilayer structure including different materials through a plurality of deposition operations according to some example embodiments. In this case, the semiconductor device 100a of FIG. 4A may be provided.

Referring to FIG. 9H, an etch-back operation may be performed on the second opening OP2 to expose the insulating pattern 191I.

By performing the etch-back operation, the second dielectric layer 172′ and the semiconductor spacer layer 171′ disposed on the bottom surface of the second opening OP2 are removed, and the first upper insulating layer 192 is removed to expose the insulating pattern 191I. In this operation, portions of the semiconductor spacer layer 171′ and the second dielectric layer 172′ disposed on the bottom surface of the second opening OP2 remain according to conditions of the etch-back operation, and the semiconductor device 100c of FIG. 4C may be provided.

Referring to FIG. 9I, a wet etching operation may be performed to expose the first channel pad 145.

In some example embodiment, the wet etching operation may include first and second wet etching operations. The first wet etching operation may be used to selectively remove the insulating pattern 191I exposed through the etch-back operation from the semiconductor spacer layer 171′ and the first upper insulating layer 192. The capping pad 147 may be exposed by the first wet etching operation. The second wet etching operation may be used to selectively remove the capping pad 147 from the insulating pattern 191I and the semiconductor spacer layer 171′. However, according to some example embodiments, the wet etching operation may be performed as one etching operation.

In this operation, as the capping pad 147 and a portion of the first channel pad 145 are removed, the semiconductor device 100d of FIG. 4D may be provided.

Referring to FIG. 9J, a conductive material may be deposited in the second openings OP2 to form the conductive pattern 191C and the second channel layer 170′.

The conductive material may include at least one of a semiconductor material such as polycrystalline silicon, a metal material, or a metal silicide. As the second openings OP2 are filled with the conductive material, the conductive pattern 191C and the second channel layer 170′ contacting the first channel pad 145 may be formed. The first channel pad 145 and the second channel layer 170′ may be integrally formed as they are formed using the same deposition operation, but may be formed by a plurality of deposition esoperation using different conductive materials according to some example embodiments.

Referring to FIG. 9K, a second filling insulating layer 174 may be formed.

The second filling insulating layer 174 may be formed by filling the second openings OP2 with an insulating material and then performing a planarization operation. The insulating material may include, for example, silicon oxide, but is not limited thereto.

Next, referring to FIGS. 2 and 3, a second channel pad 175 is formed by forming an opening through which a portion of the second filling insulating layer 174 is removed, and the second channel pad 175 is formed in the resulting opening. A third upper insulating layer 194 is formed on the second channel pad 175 and the second upper insulating layer 193, and a stud 181 is formed penetrating the third upper insulating layer 194 and contacting the second channel pad 175. A fourth upper insulating layer 195 is formed on the third upper insulating layer 194, and contact plugs 182 are formed penetrating the fourth upper insulating layer 195 and contacting the stud 181. An upper interconnection 183 is formed on contact plugs 182. Therefore, the semiconductor devices of FIGS. 1A to 3 may be formed.

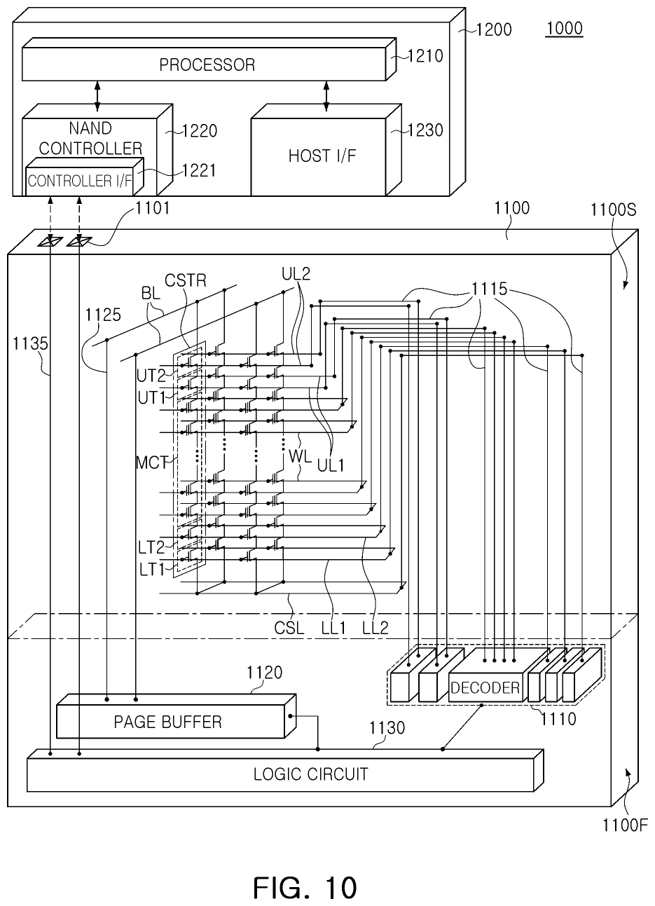

FIG. 10 is a schematic diagram illustrating a data storage system including a semiconductor device according to some example embodiments.

Referring to FIG. 10, a data storage system 1000 may include a semiconductor device 1100 and a controller 1200 electrically connected to the semiconductor device 1100. The data storage system 1000 may be a storage device including one or a plurality of semiconductor devices 1100 or an electronic device including the storage device. For example, the data storage system 1000 may be a solid state drive device (SSD), a universal serial bus (USB), a computing system, a medical device, and/or a communication device, including one or a plurality of semiconductor devices 1100.

The semiconductor device 1100 may be a non-volatile memory device, and may be, for example, a NAND flash memory device as described above with reference to FIGS. 1 to 8B. The semiconductor device 1100 may include a first semiconductor structure 1100F and a second semiconductor structure 1100S on the first semiconductor structure 1100F. In some example embodiments, the first semiconductor structure 1100F may be disposed next to the second semiconductor structure 1100S. The first semiconductor structure 1100F may be a peripheral circuit structure including a decoder circuit 1110, a page buffer 1120, and a logic circuit 1130. The second semiconductor structure 1100S may be a memory cell structure including a bit line BL, a common source line CSL, word lines WL, first and second upper gate lines UL1 and UL2, and first and second gate lower lines LL1 and LL2, and memory cell strings CSTR between the bit line BL and the common source line CSL.

In the second semiconductor structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously modified according to some example embodiments.

In some example embodiments, the upper transistors UT1 and UT2 may include a string select transistor, and the lower transistors LT1 and LT2 may include a ground select transistor. The lower gate lines LL1 and LL2 may be gate electrodes of the lower transistors LT1 and LT2, respectively. The word lines WL may be gate electrodes of the memory cell transistors MCT, and the upper gate lines UL1 and UL2 may be gate electrodes of the upper transistors UT1 and UT2, respectively.

In some example embodiments, the lower transistors LT1 and LT2 may include a lower erase control transistor LT1 and a ground select transistor LT2 connected in series. In this embodiment, the lower gate lines LL2 of the ground select transistor LT2 may mean the lower gate electrode 130G of FIG. 2. The upper transistors UT1 and UT2 may include a string select transistor UT1 and an upper erase control transistor UT2 connected in series. At least one of the lower erase control transistor LT1 and the upper erase control transistor UT2 may be used for an erase operation of erasing data stored in the memory cell transistors MCT by using the GIDL phenomenon. In this embodiment, the upper gate line UL1 of the string select transistor UT1 may mean the second gate electrode 150 of FIG. 2.

The common source line CSL, the first and second lower gate lines LL1 and LL2, the word lines WL, and the first and second upper gate lines UL1 and UL2 may be electrically connected to the decoder circuit 1110 through first connection interconnections 1115 extending from the inside of the first semiconductor structure 1100F to the second semiconductor structure 1100S. The bit lines BL may be electrically connected to the page buffer 1120 through second connection interconnections 1125 extending from the inside of the first semiconductor structure 1100F to the second semiconductor structure 1100S.

In the first semiconductor structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection interconnection 1135 extending from the inside of the first semiconductor structure 1100F to the second semiconductor structure 1100S.

The controller 1200 may include a processor 1210, a NAND controller 1220, and a host interface (I/F) 1230. In some embodiments, the data storage system 1000 may include a plurality of semiconductor devices 1100, and in this case, the controller 1200 may control the plurality of semiconductor devices 1100.

The processor 1210 may control the overall operation of the data storage system 1000 including the controller 1200. The processor 1210 may operate according to predetermined firmware, and may access the semiconductor device 1100 by controlling the NAND controller 1220. The NAND controller 1220 may include a NAND interface 1221 that processes communication with the semiconductor device 1100. Through the NAND interface 1221, a control command used to control the semiconductor device 1100, data to be written to the memory cell transistors MCT of the semiconductor device 1100, data to be read from the memory cell transistors MCT, and the like may be transmitted. The host interface 1230 may provide a communication function between the data storage system 1000 and an external host. When receiving a control command from an external host through the host interface 1230, the processor 1210 may control the semiconductor device 1100 in response to the control command.

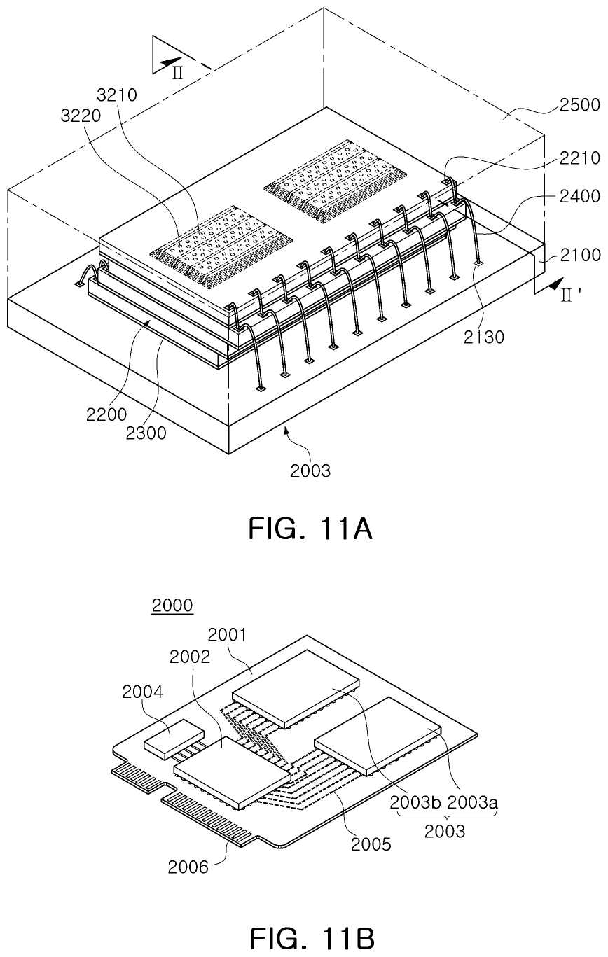

FIGS. 11A and 11B are perspective views of a data storage system including a semiconductor device according to some example embodiments, where FIG. 11A is an expanded vie of a semiconductor package 2003 of FIG. 11B.

Referring to FIGS. 11A and 11B, a data storage system 2000 according to some example embodiments of present inventive concepts may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to an external host. The number and arrangement of the plurality of pins in the connector 2006 may vary according to a communication interface between the data storage system 2000 and the external host. In some example embodiments, the data storage system 2000 may communicate with an external host according to any one of the interfaces such as a Universal Serial Bus (USB), Peripheral Component Interconnect Express (PCI-Express), Serial Advanced Technology Attachment (SATA), an M-Phy for Universal Flash Storage (UFS), and the like. In some example embodiments, the data storage system 2000 may operate using power supplied from an external host through the connector 2006. The data storage system 2000 may further include a power management integrated circuit (PMIC) used to distribute power supplied from the external host to the controller 2002 and the semiconductor package 2003.

The controller 2002 may write data to or read data from the semiconductor package 2003, and may improve the operating speed of the data storage system 2000.

The DRAM 2004 may be a buffer memory used to reduce a speed difference between the semiconductor package 2003 as a data storage space and an external host. The DRAM 2004 included in the data storage system 2000 may also operate as a kind of cache memory, and may provide a space for temporarily storing data in a control operation for the semiconductor package 2003. For example, when the data storage system 2000 includes the DRAM 2004, the controller 2002 may further include a DRAM controller to control the DRAM 2004 in addition to the NAND controller used to control the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 disposed on lower surfaces of the semiconductor chips 2200, respectively, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including upper package pads 2130. Each semiconductor chip 2200 may include an input/output pad 2210. The input/output pad 2210 may correspond to the input/output pad 1101 of FIG. 10. Each of the semiconductor chips 2200 may include gate stack structures 3210 and channel structures 3220. Each of the semiconductor chips 2200 may include the semiconductor device described above with reference to FIGS. 1 to 7.

In some example embodiments, the connection structure 2400 may be a bonding wire electrically connecting the input/output pad 2210 and the upper package pads 2130. Accordingly, in each of the first and second semiconductor packages 2003a and 2003b, the semiconductor chips 2200 may be electrically connected to each other using a bonding wire method, and may be electrically connected to the upper package pads 2130 of the package substrate 2100. According to some example embodiments, in each of the first and second semiconductor packages 2003a and 2003b, the semiconductor chips 2200 may also be electrically connected to each other using a connection structure including a Through Silicon Via (TSV) instead of the connection structure 2400 of the bonding wire method.

In some example embodiments, the controller 2002 and the semiconductor chips 2200 may be included in one package. In some example embodiments, the controller 2002 and the semiconductor chips 2200 may be mounted on a separate interposer substrate different from the main board 2001, and the controller 2002 and the semiconductor chips 2200 may be connected to each other by interconnections formed on the interposer substrate.

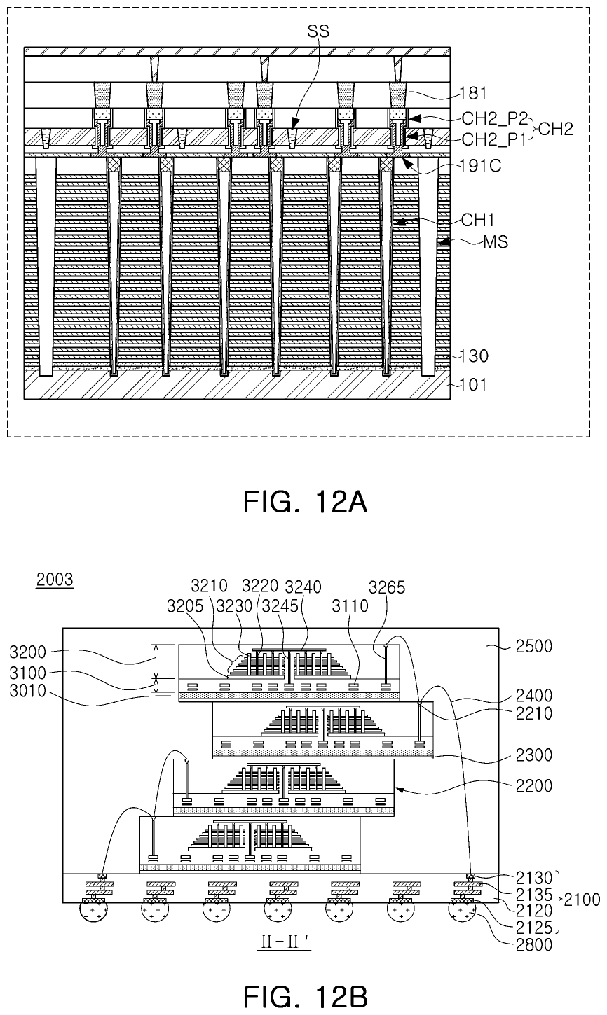

FIGS. 12A and 12B are cross-sectional views illustrating a semiconductor package according to some example embodiments. FIG. 12B illustrates some example embodiments of the semiconductor package 2003 of FIGS. 11A and 11B taken along line II-IF of the semiconductor package 2003 of FIG. 11A, and FIG. 12A illustrates an enlarged view of a region of second semiconductor structure 3200 of FIG. 12B.

Referring to FIGS. 12A and 12B, in the semiconductor package 2003, the package substrate 2100 may be a printed circuit board. The package substrate 2100 may include a package substrate body 2120, package upper pads 2130 disposed on an upper surface of the package substrate body 2120, lower pads 2125 disposed on or exposed through the lower surface of the package substrate body 2120, and internal interconnections 2135 electrically connecting the upper pads 2130 and the lower pads 2125 inside the package substrate body 2120. The upper pads 2130 may be electrically connected to the connection structures 2400. The lower pads 2125 may be connected to the interconnection patterns 2005 of the main board 2001 of the data storage system 2000 as illustrated in FIG. 11B through conductive connection portions 2800.

Each of the semiconductor chips 2200 may include a semiconductor substrate 3010, and a first semiconductor structure 3100 and a second semiconductor structure 3200 that are sequentially stacked on the semiconductor substrate 3010. The first semiconductor structure 3100 may include a peripheral circuit region including peripheral interconnections 3110. The second semiconductor structure 3200 may include a common source line 3205, a gate stack structure 3210 on the common source line 3205, channel structures 3220 and separation regions 3230 passing through the gate stack structure 3210, bit lines 3240 electrically connected to the memory channel structures 3220, and cell contact plugs 3265 electrically connected to the word lines WL (see FIG. 10) of the gate stack structure 3210. As described above with reference to FIGS. 1 to 8B, in each of the semiconductor chips 2200, the second channel structures CH2 passing through the second gate electrode 150 may include a first portion CH2_P1 having a first width and a second portion CH2_P2 having a second width, greater than the first width.

Each of the semiconductor chips 2200 may include a through interconnection 3245 electrically connected to the peripheral interconnections 3110 of the first semiconductor structure 3100 and extending into the second semiconductor structure 3200. The through interconnection 3245 may be disposed outside the gate stack structure 3210, and may be further disposed to pass through the gate stack structure 3210. Each of the semiconductor chips 2200 may further include an input/output pad 2210 (refer to FIG. 11A) electrically connected to the peripheral interconnections 3110 of the first semiconductor structure 3100.

As set forth above, a semiconductor device may have improved integration and/or reliability by securing a contact area with a stud by forming second channel structures having bent portions, and a data storage system including the semiconductor device, may be provided.

While example embodiments have been illustrated and described above, it will be apparent to those skilled in the art that modifications and variations could be made without departing from the scope of present inventive concepts as defined by the appended claims.

1. A semiconductor device comprising:
a substrate;
first gate electrodes spaced apart from each other and stacked on the substrate;
first channel structures extending through the first gate electrodes in a first direction that is perpendicular with respect to a surface of the substrate, wherein each of the first channel structures respectively includes a first channel layer and a first dielectric layer between the first channel layer and each of the first gate electrodes;
separation regions extending through the first gate electrodes in the first direction and extending in a second direction that is parallel with respect to the surface of the substrate, and wherein adjacent ones of the separation regions are spaced apart from each other in a third direction that is perpendicular with respect to the first and second directions and that is parallel with respect to the surface of the substrate;
an insulating layer on the first channel structures and the separation regions, wherein the separation regions are between the insulating layer and the substrate;
a plurality of conductive patterns passing through the insulating layer, wherein each of the conductive patterns is connected to a respective one of the first channel structures;
a second gate electrode on the insulating layer;
second channel structures extending through the second gate electrode, wherein each of the second channel structures respectively includes a second channel layer connected to a respective one of the conductive patterns and a second dielectric layer between the second channel layer and the second gate electrode; and
isolation regions extending through the second gate electrode, wherein the insulating layer is between the isolation regions and the substrate,
wherein each of the first channel structures includes a respective first region overlapping a respective one of the second channel structures in the first direction, and a respective second region that is non-overlapping with the respective one of the second channel structures in the first direction, and
wherein each of the second channel structures includes a first portion having a first width in the third direction and a second portion having a second width in the third direction that is greater than the first width, wherein the first portion is between the second portion and the substrate.

2. The semiconductor device of claim 1, wherein each of the conductive patterns includes a first side surface in contact with the insulating layer such that the respective one of the first channel structures is between the first side surface and the substrate in the first direction, and a second side surface in contact with the insulating layer such that the second side surface is spaced apart from the respective one of the first channel structures in the third direction.

3. The semiconductor device of claim 1, wherein a thickness of the second gate electrode is greater than a thickness of each of the first gate electrodes, and
wherein each of the first gate electrodes includes a first material, and wherein the second gate electrode includes a second material different than the first material.

4. The semiconductor device of claim 1, wherein the first portion extends through the second gate electrode, and wherein the second gate electrode is between the second portion and the substrate.

5. The semiconductor device of claim 1, wherein each of the second channel structures further includes a third portion extending from the first portion toward the substrate, and wherein the third portion has a third width greater than the first width.

6. The semiconductor device of claim 5, wherein the third portion is between the second gate electrode and the substrate.

7. The semiconductor device of claim 5, wherein each of the second channel structures further comprises a semiconductor spacer layer between the second channel layer and the second dielectric layer in the first portion and in the second portion, and wherein the second channel layer is in direct contact with the second dielectric layer in the third portion.

8. The semiconductor device of claim 1, wherein the second width of the second portion is greater than a width of each of the first channel structures in the third direction.

9. The semiconductor device of claim 1, wherein each of the isolation regions includes a first surface between a second surface and the substrate, and wherein a distance between the second surfaces and the substrate is less than a distance between the substrate and surfaces of the second portions of the second channel structures that are spaced apart from the second gate electrode.

10. The semiconductor device of claim 9, wherein each of the second channel structures includes a bent portion defined by the first portion and the second portion, wherein the bent portion is adjacent to the second gate electrode, and wherein a distance between the bent portion and the substrate is the same as the distance between the second surfaces of the isolation regions and the substrate.

11. The semiconductor device of claim 1, wherein the first dielectric layer has a multi-layer structure, and wherein the second dielectric layer has a single layer structure.

12. The semiconductor device of claim 1, further comprising a cell region insulating layer on the first gate electrodes and on side surfaces of the first channel structures, wherein the cell region insulating layer is between the insulating layer and the first gate electrodes,
wherein each of the first channel structures includes a first channel pad connected to the first channel layer,
wherein each of the conductive patterns includes a first conductive portion on the cell region insulating layer and a second conductive portion on the first channel pad, and
wherein a distance between the first conductive portion and the substrate is greater than a distance between the second conductive portion and the substrate.

13. A semiconductor device comprising:
a substrate;
gate electrodes spaced apart from each other and stacked in a first direction that is perpendicular with respect to a surface of the substrate;
channel structures passing through the gate electrodes, extending in the first direction, and respectively including a channel layer and a dielectric layer between the channel layer and the gate electrodes;
an insulating layer on the channel structures;
a conductive pattern passing through the insulating layer and connected to the channel structures;
an upper horizontal conductive layer on the insulating layer and the conductive pattern, and
vertical semiconductor structures connected to the conductive pattern by penetrating through the upper horizontal conductive layer,
wherein each of the vertical semiconductor structures includes a first portion penetrating through the upper horizontal conductive layer, a second portion on the first portion, and a third portion below the first portion,
wherein the second portion covers a portion of an upper surface of the upper horizontal conductive layer, and
wherein the third portion covers a portion of a lower surface of the upper horizontal conductive layer.

14. The semiconductor device of claim 13, wherein the first to third portions are integrally connected, and
wherein a first width of the first portion is smaller than a second width of the second portion or a third width of the third portion.

15. The semiconductor device of claim 13, wherein the upper horizontal conductive layer is a string select gate electrode, and wherein the vertical semiconductor structure is a string select channel structure.

16. The semiconductor device of claim 13, further comprising
separation regions passing through the gate electrodes, extending in the first direction and in a second direction that is parallel with respect to the surface of the substrate, and spaced apart from each other in a third direction that is parallel with respect to the surface of the substrate, wherein the upper horizontal conductive layer is located at a higher level than a level of the separation regions.

17. The semiconductor device of claim 16, further comprising
isolation regions located at a level higher than the level of the separation regions, penetrating through the upper horizontal conductive layer, and spaced apart from each other in the third direction,
wherein in a plane, a distance between the separation regions adjacent to each other is greater than a distance between the isolation regions adjacent to each other.

18. A data storage system comprising:
a semiconductor storage device including,
a first substrate,
circuit elements on one side of the first substrate,
a second substrate on the circuit elements,
gate electrodes spaced apart from each other and stacked in a first direction that is perpendicular with respect to a surface of the second substrate, wherein the gate electrodes are stacked between the first and second substrates,
channel structures extending through the gate electrodes in the first direction, wherein each of the channel structures respectively includes a channel layer and a dielectric layer between the channel layer and the gate electrodes,
an insulating layer on the channel structures,
a plurality of conductive patterns passing through the insulating layer, wherein each of the conductive patterns is connected to a respective one of the channel structures,
a conductive layer on the insulating layer and the conductive patterns,
a plurality of semiconductor structures extending through the conductive layer, wherein each of the semiconductor structures is connected to a respective one of the conductive patterns, and
an input/output pad electrically connected to at least one of the circuit elements; and
a controller electrically connected to the semiconductor storage device through the input/output pad, wherein the controller is configured to control the semiconductor storage device,
wherein each of the semiconductor structures includes a first portion extending through the conductive layer, a second portion on the first portion, and a third portion between the first portion and the gate electrodes,
wherein the second portion is on a portion of a first surface of the conductive layer opposite the gate electrodes, and
wherein the third portion is on a portion of a second surface of the conductive layer adjacent the gate electrodes.

19. The data storage system of claim 18, wherein each of the channel structures includes a first region at least partially overlapping a respective one of the semiconductor structures in the first direction, and a remaining second region, and
wherein the first portion has a first width in a second direction that is perpendicular with respect to the first direction,
wherein the second portion has a second width in the second direction,
wherein the first width of the first portion is less than the second width of the second portion.

20. The data storage system of claim 19, further comprising:
a plurality of isolation regions extending through the conductive layer, wherein each of the isolation regions extends in a third direction that is perpendicular with respect to the first and second directions, and wherein each of the isolation regions is spaced apart from the gate electrodes.

21.-25. (canceled)
